(19) United States
(12) Patent Application Publication
(10) Pub. No.: US 2016/0077134 A1
(43) Pub. Date: Mar. 17, 2016

(54) ENHANCED RADAR DETECTION FOR COMMUNICATION NETWORKS

(71) Applicant: QUALCOMM Incorporated, San Diego, CA (US)

(72) Inventors: Meriam Khufu Ragheb Rezk, Campbell, CA (US); Shay Israel Freundlich, Sunnyvale, CA (US)

(21) Appl. No.: 14/485,538

(22) Filed: Sep. 12, 2014

(51) Int. Cl. G01R 19/165

(52) U.S. Cl. CPC G01R 19/16585

(57) ABSTRACT

A network device is disclosed for determining whether a received signal includes a radar signal. The network device can determine a beginning of a pulse within the signal as the time instant at which a power level of the signal exceeds an upper threshold. The network device can determine an end of the pulse as the time instant at which a drop in the power level associated with the signal exceeds a power drop threshold. The network device determines whether the pulse is part of the radar signal based, at least in part, on the beginning of the pulse and the end of the pulse. In some embodiments, the network device may cancel a DC offset from the signal prior to determining whether the signal includes a radar signal.

### BACKGROUND

Embodiments of the disclosure generally relate to the field of communication systems and, more particularly, to radar detection in a wireless communication system.

Wireless devices can be configured to operate with RAdio Detection And Ranging (radar) devices by sharing frequencies in the 5 GHz frequency band. For example, a wireless device can vacate operations in the shared frequency band when radar signals are detected to avoid interfering with the radar devices. Detecting radar signals can be difficult due to signal interference and/or communication activity of the wireless device. False radar signal detection can cause the wireless device to unnecessarily vacate the shared frequency band.

### SUMMARY

Various embodiments are disclosed for detecting radar signals. In some embodiments, a network device determines a beginning of a pulse within a signal received by the network device based, at least in part, on comparing a power level of the signal against an upper threshold. The network device determines an end of the pulse within the received signal based, at least in part, on determining that a drop in the power level associated with the signal exceeds a power drop threshold. The network device determines whether the pulse is a radar pulse based, at least in part, on determining the beginning of the pulse and the end of the pulse.

### BRIEF DESCRIPTION OF THE DRAWINGS

The present disclosure may be better understood, and numerous objects, features, and advantages made apparent to those skilled in the art by referencing the accompanying drawings.

FIG. 1 is an example block diagram of a network device including a mechanism for radar signal detection;

FIG. 2 is an example block diagram illustrating a mechanism for radar detection after DC offset cancellation;

FIG. 3A is a block diagram of one embodiment of a radar detection module;

FIG. 3B is an example block diagram of a receiver including a radar detection module;

FIG. 4 is a block diagram of a receiver including an example DC offset cancellation module;

FIG. 5 is a flow diagram illustrating example operations for detecting a radar pulse within a received signal;

FIG. 6 is a flow diagram illustrating example operations for DC offset cancellation prior to radar detection;

FIG. 7 is an example graph of signal amplitude versus time illustrating DC offset estimation;

FIG. 8 is a flow diagram illustrating operations of one embodiment of estimating pulse characteristics for radar detection;

FIG. 9 is a flow diagram illustrating operations of another embodiment of estimating pulse characteristics for radar detection;

FIG. 10A is a graph of in-band signal power versus time illustrating one embodiment for radar detection;

FIG. 10B is a graph of in-band signal power versus time illustrating another embodiment for radar detection; and

FIG. 11 is a block diagram of one embodiment of an electronic device including a mechanism for radar detection.

### DESCRIPTION OF EMBODIMENT(S)

The description that follows includes exemplary systems, methods, techniques, instruction sequences, and computer program products that embody techniques of the disclosure. However, it is understood that the described embodiments may be practiced without these specific details. For instance, although examples refer to wireless local area network (WLAN) devices executing operations for radar detection, embodiments are not so limited. In other embodiments, operations for radar detection may be implemented by network devices that implement other suitable wireless communication protocols with an operating frequency band that partially or completely overlaps with the operating frequency band of a radar protocol. For example, network devices that implement Worldwide Interoperability for Microwave Access (WiMAX) communication protocols may execute the operations for radar detection. In other instances, well-known instruction instances, protocols, structures, and techniques have not been shown in detail in order not to obfuscate the description.

Wireless devices may share an operating spectrum with radar devices in the 5 GHz frequency band. A wireless device may be configured to detect radar signals and temporarily abort operations in the frequency band when radar signals are detected within the frequency band. The wireless device may perform DC offset cancellation prior to detecting radar signals. DC offset cancellation may involve removing a DC offset that is introduced by a receiver of the wireless device during processing operations of the receiver (e.g., during analog-to-digital conversion). The DC offset associated with the receiver may be removed from a received baseband signal by using high-pass filters or by notching the DC frequency. However, this may not be feasible for applications that transmit/receive information at or near the DC frequency (i.e., 0 Hz). For example, a radar signal may include information at or near the DC frequency. Therefore, notching or filtering the received baseband signal may hinder the ability of the wireless device to detect the radar signal in the received baseband signal. In some wireless devices, a received baseband signal may be partially notched up to a predetermined DC notch limit in order to reduce the likelihood of removing a potential radar signal from the received baseband signal. However, the ability to detect the radar signal after partial notching relies on the selection of the DC notch limit. If the DC notch limit is too high, the amplitude of the radar signal (within the received baseband signal) at the DC frequency may be lower than the DC notch limit. In this scenario, the radar signal may be removed from the received baseband signal thereby hindering the ability to detect the radar signal at the DC frequency. If the DC notch limit is too low, the remaining DC offset after partial notching may incorrectly trigger detection of a radar pulse or miss the radar pulse because of an incorrect gain setting selection.

In some embodiments, an adaptive DC offset estimator can estimate and track changing DC offsets in a receiver of a wireless device. The DC offset estimator can estimate the DC offset associated with the receiver during a quiet time interval, i.e., when no radio signals are being received. Once the DC offset converges to a steady-state value, the DC offset estimator can use the steady-state value of the DC offset (“DC offset estimate”) to minimize the DC offset associated with the receiver from baseband signals that are subsequently received at the network device. The baseband signal after DC offset cancellation may be further analyzed to determine whether the baseband signal includes a radar pulse at DC frequency. A pulse detector can determine the beginning of a pulse within the baseband signal by detecting an increase in received signal power above an upper threshold. In some embodiments, the pulse detector can determine the end of the pulse by detecting that the received signal power decreases below a power threshold and remains below the power threshold for a time interval. In other embodiments, the pulse detector can determine the end of the pulse by detecting that the received signal power drops by a certain amount for the time interval. The time interval may be determined based, at least in part, on the maximum time it takes a chirp radar pulse to cross DC. The pulse detector can determine whether the pulse is a radar pulse based, at least in part, on determining the beginning and the end of the pulse. Minimizing the DC offset associated with the receiver from the baseband signal can minimize false detection of a radar pulse within the baseband signal at DC frequency. Additionally, determining the end of the pulse based on a drop in the received signal power for a time interval can minimize the possibility of false detection of the end of the pulse.

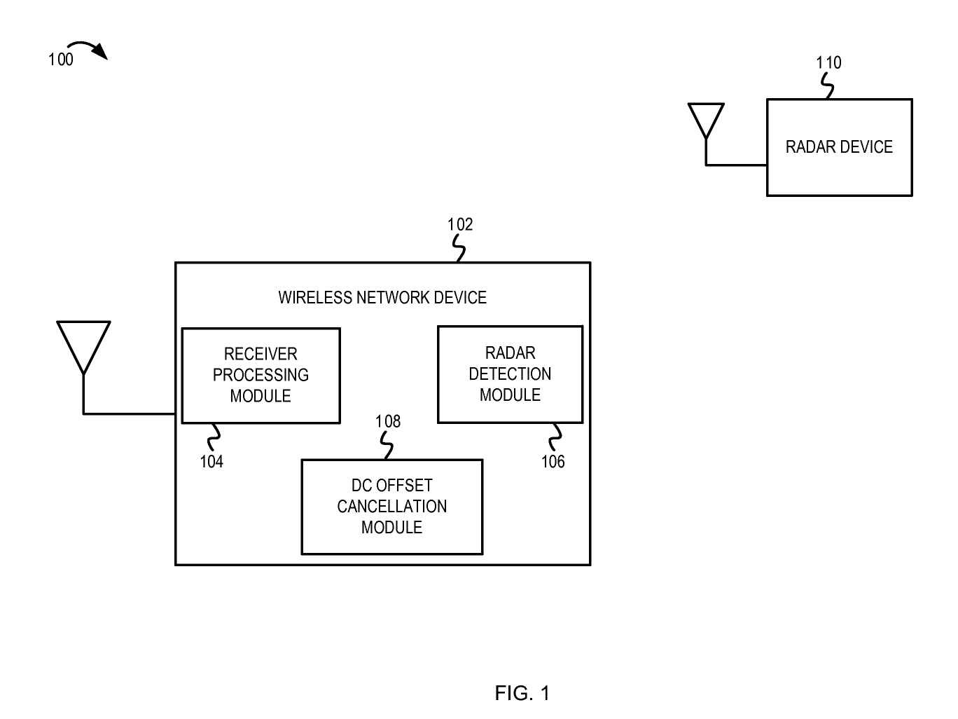

FIG. 1 is an example block diagram of a network device including a mechanism for radar signal detection. FIG. 1 depicts a communication network 100 including a wireless network device 102 and a radar device 110. The wireless network device 102 includes a receiver processing module 104, a radar detection module 106, and a DC offset cancellation module 108. In one embodiment, the wireless network device 102 may be a standalone or dedicated wireless local area network (WLAN) device (e.g., a WLAN access point or a WLAN client device) that implements IEEE 802.11 communication protocols. In other embodiments, the wireless network device 102 may be another suitable electronic device, such as a laptop computer, a tablet computer, a wireless access point, a wireless-enabled display, a mobile phone, a smart appliance, or another electronic device that is configured to implement wireless communication protocols. In some embodiments, the receiver processing module 104, the radar detection module 106, and/or the DC offset cancellation module 108 may be implemented as part of a receiver of the wireless network device 102. In some embodiments, the receiver may be a direct conversion receiver. A direct conversion receiver may demodulate radio signals directly into a baseband signal. The baseband signal is a low pass signal that includes frequencies at or near DC frequency (i.e., 0 Hz). In other embodiments, the receiver may be another suitable type of receiver (e.g., a superheterodyne receiver).

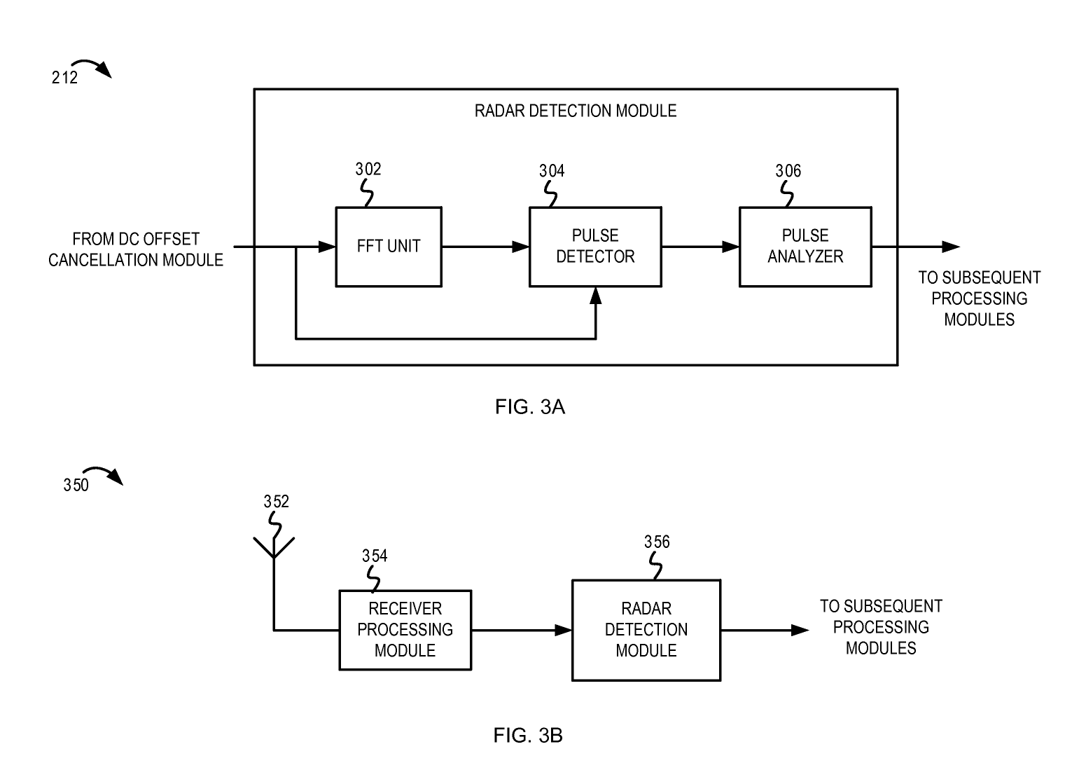

Radio signals (also referred to as radio frequency signals or RF signals) may be received by an antenna and provided to the receiver processing module 104. The receiver processing module 104 may include an amplifier to amplify the received signal, a filter to remove unwanted bands of frequencies, and/or a mixer to down-convert the received signal. In some embodiments, the mixer may down-convert the received radio signal to a received baseband signal. In other embodiments, the receiver may demodulate radio signals directly into the baseband signal without the mixer. The receiver processing module 104 may also include an automatic gain controller (AGC) to adjust the gain to an appropriate level for a range of received signal amplitude levels. The receiver processing module 104 may also include an analog-to-digital converter (ADC) to convert the received signal from an analog representation to a digital representation. The DC offset cancellation module 108 may adaptively estimate and track the DC offset in the receiver of the wireless network device 102. In one embodiment, the DC offset cancellation module 108 can analyze the baseband signal at the output of the receiver processing module 104 during a “quiet time interval” when no radio signals are being received at the wireless network device 102. The DC offset cancellation module 108 may iteratively estimate the DC offset associated with the receiver based, at least in part, on the output of the receiver processing module 104. In one embodiment, DC offset cancellation module 108 may latch or record the value of the DC offset estimate when the quiet time interval elapses. In another embodiment, the DC offset cancellation module 108 may record the value of the DC offset estimate once the DC offset estimate converges to a steady-state value. The DC offset cancellation module 108 can use DC offset estimate to vary/adjust the DC offset associated with the receiver from the baseband representation of subsequently received radio signals. For example, the DC offset cancellation module 108 can use DC offset estimate to minimize the DC offset associated with the receiver. The DC offset estimate can be re-determined periodically or can be updated if a new DC offset estimate is substantially different from the current DC offset estimate. Operations of the DC offset estimation module 108 will be further described in FIGS. 3, 4, and 6.

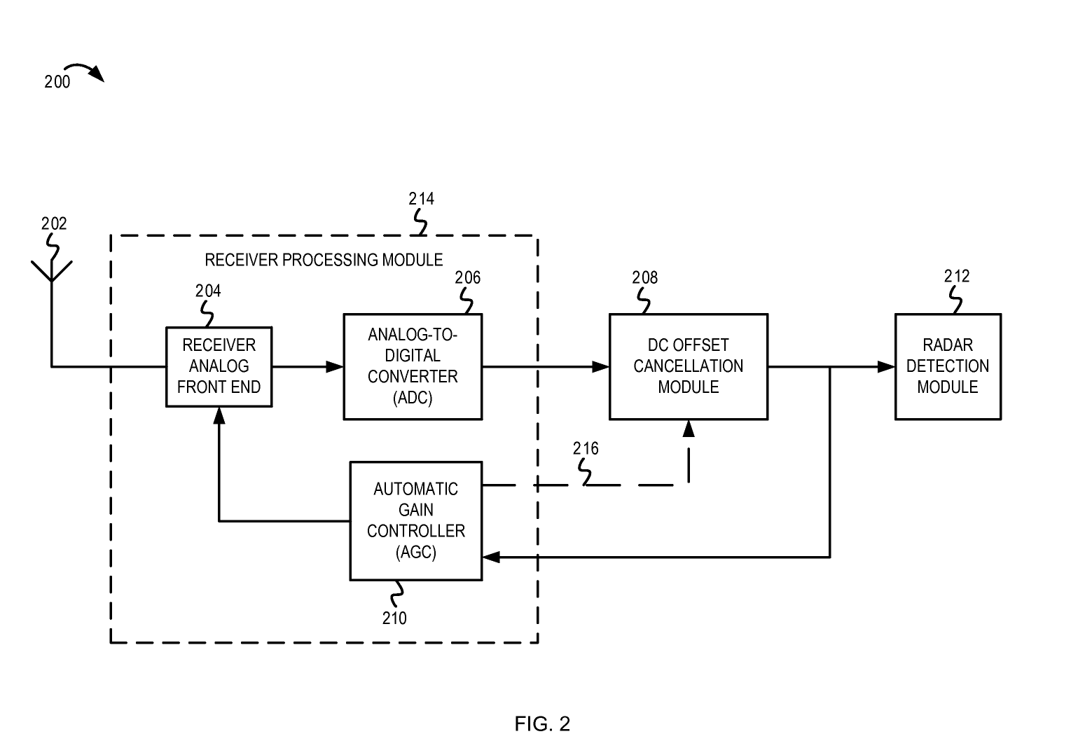

In some embodiments, the radar detection module 106 may further analyze the resultant baseband signal after DC offset cancellation to determine whether the baseband signal includes a radar pulse at DC frequency. The radar detection module 106 can determine the beginning of the pulse by detecting an increase in received signal power or received signal amplitude. For example, the radar detection module 106 can determine the beginning of the pulse by detecting that the received signal power exceeds an upper threshold. The radar detection module 106 can determine the end of the pulse by detecting a decrease in the received signal power or the received signal amplitude. In one embodiment, the radar detection module 106 can determine the end of the pulse by detecting that the received signal power decreases by a configurable power drop value for a time interval. In another embodiment, the radar detection module 106 can determine the end of the pulse by detecting that the received signal power falls below a lower threshold and remains below the lower threshold for a time interval. In both embodiments, the time interval can help filter out transient changes that may incorrectly register as a falling edge of the pulse. In some embodiments, the time interval may be a programmable time interval. In other embodiments, the time interval may be a preset or hardcoded time interval. In other embodiments, the time interval may be dynamically determined by the radar detection module 106. For example, the time interval may be computed by the radar detection module 106. The radar detection module 106 can determine characteristics of the pulse (“pulse characteristics”) based, at least in part, on the beginning of the pulse and the end of the pulse and determine whether the pulse is a radar pulse using those characteristics. Operations of the radar detection module 106 will be further described in FIGS. 2, 5, and 8-10B.

FIG. 2 is an example block diagram illustrating a mechanism for radar detection after DC offset cancellation. FIG. 2 depicts a receiver 200 including an antenna 202, a receiver processing module 214, a DC offset cancellation module 208, and a radar detection module 212. The receiver processing module 214 includes a receiver analog front end (AFE) 204, an ADC 206, and an AGC 210. In one embodiment, the receiver 200 can be a WLAN receiver included in a wireless device. For example, the receiver 200 may be implemented in an electronic device, such as a laptop computer, a tablet computer, a wireless access point, a wireless-enabled display, a mobile phone, a smart appliance, or other electronic devices that are configured to implement wireless communication protocols (e.g. IEEE 802.11 protocols). As another example, in a multiple-input multiple-output (MIMO) wireless system (not shown), a single radar detection module 212 may be used in conjunction with multiple receivers.

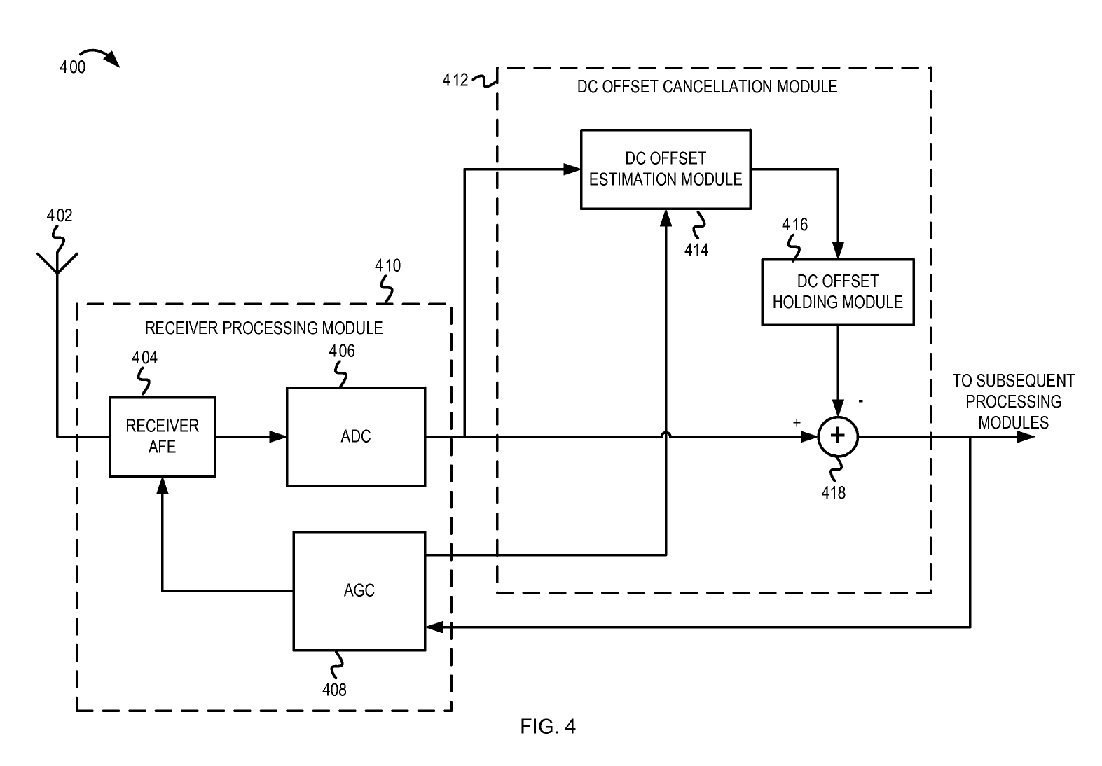

The antenna 202 receives an RF signal and provides the RF signal to the receiver AFE 204. The receiver AFE 204 may include an amplifier to amplify the received signal, a filter to remove unwanted bands of frequencies, and/or a mixer to down-convert the received signal. The output of the receiver AFE 204 is provided to the ADC 206. For example, the antenna 202 may receive a WLAN signal and may provide the WLAN signal to the input of a variable gain amplifier (VGA) of the receiver AFE 204. In some embodiments, the output of the VGA (not shown in FIG. 2) may be further processed and then provided to the ADC 206. In some embodiments, the mixer may down-convert the received RF signal to a received baseband signal. In other embodiments, the receiver 200 may be a direct conversion receiver that demodulates the RF signal directly into the baseband signal without a mixer. The baseband signal at the output of the receiver AFE 204 may be provided to the ADC 206. The ADC 206 can convert the baseband signal from an analog representation to a corresponding digital representation. The output of the ADC 206 is provided to the DC offset cancellation module 208. The DC offset cancellation module 208 may estimate the DC offset associated with the receiver 200. The DC offset associated with the receiver 200 may include the DC offset injected by processing components into the received signal at each stage of received signal processing. For example, a receive mixer, a local oscillator, an amplifier, an impedance matching component, a filter, and/or another receiver processing component may each inject a DC offset into the received signal during their respective processing stage. The DC offset injected by each of the receiver processing components may be collectively referred to as the DC offset associated with the receiver 200. The DC offset cancellation module 208 may initiate a quiet time interval at the receiver 200 so that the receiver 200 does not receive any RF signals. The DC offset cancellation module 208 may use a suitable DC offset estimation technique to estimate the DC offset associated with the receiver 200 (“current DC offset estimate”) from the output of the ADC 206 during the quiet time interval. The DC offset cancellation module 208 may determine the current DC offset estimate once the quiet time interval elapses as will be further described in FIG. 4. The DC offset cancellation module 208 may also cancel a portion of a DC component of the baseband signal that is attributable to the DC offset associated with the receiver 200. For example, the DC offset cancellation module 208 can subtract the current DC offset estimate from each sample of the baseband signal generated at the output of the ADC 206 as will be further described in FIG. 4. The output of the DC offset cancellation module 208 may be the baseband signal at the input of the DC offset cancellation module 208 but with a minimized DC offset associated with the receiver 200.

The output of the DC offset cancellation module 208 is coupled with the AGC 210. The AGC 210 can monitor the output of the DC offset cancellation module 208 and can adjust the gain of the receiver AFE 204 to an appropriate level for a range of received signal amplitude levels. In one implementation, the AGC 210 may determine whether to increase or decrease a gain setting of a VGA to size the baseband signal. The baseband signal provided from the receiver AFE 204 to the ADC 206 can be sized so as not to saturate the ADC 206. For example, if the output of the DC offset cancellation module 208 is saturated, the AGC 210 may reduce the gain setting of the receiver AFE 204 (e.g., the VGA). As another example, if the output of the DC offset cancellation module 208 is too small, the AGC 210 may increase the gain setting of the receiver AFE 204.

In addition to controlling the gain setting of the receiver AFE 204, the AGC 210 may also provide a control signal 216 (depicted using dashed lines) to the DC offset cancellation module 208 to indicate a change in the gain setting. The DC offset cancellation module 208 may re-estimate the DC offset associated with the receiver 200 in response to receiving the control signal 216. In another embodiment, the DC offset cancellation module 208 may continuously estimate a new DC offset associated with the receiver 200. In another embodiment, the DC offset cancellation module 208 may estimate the new DC offset associated with receiver 200 after a time interval elapses, in response to detecting saturation of the ADC 206, and/or another suitable trigger. In some examples, the time interval may be a programmable, hardcoded, or dynamically determined time interval. The DC offset cancellation module 208 may compare the new DC offset estimate against the current DC offset estimate to determine whether to update the current DC offset estimate. Operations for re-estimating the DC offset associated with the receiver 200 and for updating the current DC offset estimate are described in FIG. 4.

The baseband signal with a minimized DC offset (i.e., the output of the DC offset cancellation module 208) is provided to the radar detection module 212. The radar detection module 212 can determine whether the baseband signal includes a radar signal. FIG. 3A is a block diagram of one embodiment of the radar detection module 212. The radar detection module 212 includes an FFT unit 302, a pulse detector 304, and a pulse analyzer 306.

The FFT unit 302 can convert the time domain digital baseband signal from to a corresponding frequency domain signal. In some embodiments, the pulse detector 304 may analyze the frequency domain signal (also referred to as frequency spectrum) at the output of the FFT unit 302 to determine whether to execute operations for detecting the radar signal. Because radar pulses are narrowband pulses, a peak or spike in the frequency domain signal may indicate the presence of a possible radar pulse in the received signal. A peak in the frequency domain signal may be detected by comparing the amplitude associated with each frequency in the frequency domain signal against an amplitude threshold. If the amplitude associated with a frequency exceeds the amplitude threshold, this can indicate that a narrowband signal is present at the frequency.

If a peak or narrowband signal (e.g., a potential radar pulse) is detected in an in-band communication channel, the pulse detector 304 may determine that the narrowband signal could potentially correspond to a radar pulse. In-band communication channels may refer to communication channels on which the receiver 200 is configured to operate. In some embodiments, the pulse detector 304 and the pulse analyzer 306 may be activated/enabled if a narrowband signal is detected in the frequency domain signal at the output of the FFT unit 302 at or near the DC frequency. In another embodiment, the pulse detector 304 and the pulse analyzer 306 may be activated if a narrowband signal is detected within the operating frequency band of the receiver 200. Alternatively, if a narrowband signal (e.g., a potential radar pulse) is detected in an out-of-band communication channel, the pulse detector 304 may determine not to execute operations for detecting the radar signal. Out-of-band communication channels may refer to the communication channels on which the receiver 200 is configured not to operate. If the narrowband signal is detected in the out-of-band communication channel, whether the narrowband signal corresponds to a radar pulse may not affect the operation of the wireless device. In some embodiments, the pulse detector 304 and the pulse analyzer 306 may be disabled/deactivated if a narrowband signal is not detected at the DC frequency or within the operating frequency band of the receiver 200.

The baseband signal at the output of the DC offset cancellation module 208 may also be provided to the pulse detector 304. If the frequency domain signal indicates the presence of a narrowband signal, the pulse detector 304 can analyze the baseband signal to determine pulse characteristics and whether the detected pulse is a radar pulse. Determining whether the detected pulse is a radar pulse can indicate whether the baseband signal includes a radar signal. The pulse detector 304 can compare the power level of the baseband signal against an upper threshold. In some embodiments, if the power level of the baseband signal exceeds the upper threshold, the pulse detector 304 can determine the beginning of the pulse within the baseband signal. The time instant at which the power level exceeds the upper threshold may be recorded as the pulse start time. The pulse start time may also be referred to as the beginning of the pulse or the rising edge of the pulse. In some embodiments, the pulse detector 304 may initiate a detection timer in response to determining that the power level exceeds the upper threshold. The detection timer may include a first time interval to prevent false detection of the pulse. If the power level exceeds the upper threshold for at least the first time interval, the time instant at which the power level exceeded the upper threshold may be recorded as the pulse start time.

After detecting the rising edge of the pulse, the pulse detector 304 may continue to monitor the power level of the baseband signal to detect the end of the pulse. In some embodiments, the pulse detector 304 may detect a drop in the power level. For example, the pulse detector 304 may determine that the power level of the baseband signal has dropped from a first power level to a second power level. The pulse detector 304 may determine a power drop by subtracting the second power level from the first power level. In some embodiments, the first power level may correspond to the pulse start time. In other embodiments, the first power level may correspond to another time instant that precedes the time instant at which the power drop was detected. The pulse detector 304 may compare the power drop against a power drop threshold to determine whether the end of the pulse was detected. In one implementation, the pulse detector 304 may determine the end of the pulse within the baseband signal if the power drop exceeds the power drop threshold. The time instant at which the power level dropped to the second power level may be recorded at the pulse stop time. The pulse stop time may also be referred to as the end of the pulse or the falling edge of the pulse. In another embodiment, the pulse detector 304 may initiate the detection timer in response to determining that the power drop exceeds the power drop threshold. The detection timer may include a second time interval to prevent false detection of the end of the pulse. If the power drop exceeds the power drop threshold for at least the second time interval, the time instant at which the power drop exceeded the power drop threshold may be recorded as the pulse stop time.

In another embodiment, the pulse detector 304 may compare the power level of the baseband signal against a lower threshold. If the power level of the received signal drops below the lower threshold, the pulse detector 304 can determine the end of the pulse within the baseband signal. The time instant at which the power level drops below the lower threshold may be recorded as the pulse stop time or the falling edge of the pulse. In another embodiment, the pulse detector 304 may initiate a detection timer in response to determining that the power level has dropped below the lower threshold. The detection timer may include a third time interval to prevent false detection of the end of the pulse. If the power level remains below the lower threshold for at least the third time interval, the time instant at which the power level dropped below the lower threshold may be recorded as the pulse stop time.

After determining the pulse start time and the pulse stop time, the pulse analyzer 306 may determine pulse characteristics. For example, the pulse analyzer 306 may determine a pulse width by subtracting the start time of the pulse from the stop time of the pulse. In some embodiments, if multiple consecutive pulses are detected, the pulse analyzer 306 may determine the time interval between two consecutive detected pulses (“pulse repetition interval”). In some embodiments, the pulse analyzer 306 may also determine the number of pulses that were detected within a predetermined time interval. The pulse characteristics may include the pulse width, the pulse repetition interval, the number of pulses per time interval, and/or other suitable characteristics. The pulse characteristics may be used to determine whether the detected pulse is part of a radar signal. The pulse characteristics may also be used to determine the type of the radar signal that was received by the receiver 200. For example, the pulse analyzer 306 may compare the pulse characteristics with reference pulse characteristics of known radar signals to determine whether the detected pulse is part of a radar signal.

If a match is not found, the pulse analyzer 306 may determine that the detected pulse is not a radar pulse and that the baseband signal does not include a radar signal. However, if a match is found, the pulse analyzer 306 may determine that the detected pulse is a radar pulse and that the baseband signal includes a radar signal. In one embodiment, in response to detecting a radar pulse in a wireless communication channel, the pulse analyzer 306 may cause the wireless device to vacate operations in the wireless communication channel for a predetermined amount of time or until the radar signal is no longer detected. In one embodiment, the wireless device may cease all transmissions in a wireless communication channel to vacate operations in the wireless communication channel. In some embodiments, when the wireless device is configured to operate as an access point, the access point can coordinate a frequency change for itself and any other client devices communicating with the access point. In some embodiments, if a radar signal is detected, the wireless device may vacate operations only in portions of its operating frequency band that include the radar pulse. For example, the wireless device may operate in a 40 MHz operational mode (i.e., the wireless communication channel is 40 MHz wide) and detect a radar signal within a 20 MHz portion of the wireless communication channel. In this example, the wireless device may vacate operations in the 20 MHz portion of the wireless communication channel where the radar signal was detected. The wireless device can continue to operate in the 20 MHz portion of the wireless communication channel where the radar signal was not detected.

In some embodiments, a wireless device may not include a DC offset cancellation module. Instead, the wireless device may execute operations for detecting the presence of a radar signal without minimizing the DC offset introduced by a receiver of the wireless device as will be described in FIG. 3B.

FIG. 3B is an example block diagram of a receiver 350 including a radar detection module. The receiver 350 includes an antenna 352, a receiver processing module 354, and a radar detection module 356. The radar detection module 356 may include an FFT unit, a pulse detector, and a pulse analyzer as similarly described above with reference to FIG. 3A. In one embodiment, the receiver 350 can be a wireless receiver included in an electronic device such as a laptop computer, a tablet computer, a wireless access point, a wireless-enabled display, a mobile phone, a smart appliance, etc.

The antenna 352 may receive an RF signal and provide the RF signal to the receiver processing module 354 which may amplify, filter, and/or down-convert the received signal. The receiver processing module 354 may also convert the received signal from an analog representation to a digital representation. In some embodiments, the receiver processing module 354 may down-convert the RF signal to a corresponding baseband signal. In another embodiment, the receiver processing module 354 may down-convert the RF signal to an intermediate signal (a non-baseband signal) at a suitable intermediate frequency. The intermediate frequency may be between the RF signal frequency and the baseband signal frequency. In another embodiment, the receiver processing module 354 may be part of a direct conversion receiver. In another embodiment, the receiver processing module 354 may not down-convert the RF signal to a lower frequency signal. Thus, depending on the implementation, the resultant signal after analog-to-digital conversion may be a digital representation of the RF signal, a digital representation of the baseband signal, or a digital representation of the intermediate signal. The resultant signal after analog-to-digital conversion (“digital received signal”) is provided to the radar detection module 356.

The radar detection module 356 may execute operations as described above with reference to FIG. 3A to determine whether to execute operations for detecting the radar signal, to identify a pulse within the digital received signal, to determine pulse characteristics, and to determine whether the detected pulse is part of a radar signal. The radar detection module 356 can cause the wireless device (that includes the receiver 350) to vacate operations in at least a portion of the wireless communication channel where the radar signal was detected.

FIG. 4 is a block diagram of a receiver 400 including an example DC offset cancellation module. The receiver 400 includes an antenna 402, a receiver processing module 410, and a DC offset cancellation module 412. The receiver processing module 410 includes a receiver AFE 404, an ADC 406, and an AGC 408. The DC offset cancellation module 412 includes a DC offset estimation module 414, a DC offset holding module 416, and a subtractor 418. Operations of the antenna 402 and the receiver processing module 410 are described above in FIGS. 1 and 2.

The ADC 406 generates a digital representation of a baseband signal and provides the resultant digital baseband signal to the DC offset cancellation module 412. In some embodiments, the DC offset estimation module 414 may initiate a quiet time interval at the receiver 400. For example, the DC offset estimation module 414 may disable the antenna 402 or other components of the receiver processing module 410 so that the receiver 400 does not receive any RF signals during the quiet time interval. The DC offset estimation module 414 may estimate the DC offset associated with the receiver 400 from the output of the ADC 406 during the quiet time interval. The DC offset estimation module 414 may implement a suitable DC offset estimation technique. For example, the DC offset estimation module 414 may implement a leaky bucket technique for estimating the DC offset associated with the receiver 400. As another example, the DC offset estimation module 414 may include a suitable finite impulse response (FIR) or infinite impulse response (IIR) low pass filter for estimating the DC offset associated with the receiver 400. In some embodiments, the DC offset estimation module 414 may iteratively estimate the DC offset associated with the receiver 400 during the quiet time interval.

In some embodiments, the quiet time interval may be determined based, at least in part, on the bandwidth of the DC offset estimation module 414. For example, if the DC offset estimation module implements a leaky bucket filter, the quiet time interval may be determined based, at least in part, on the bandwidth of the leaky bucket filter. The bandwidth of the DC offset estimation module 414 may include a narrow frequency band centered around the DC frequency. In one implementation, after the quiet time interval elapses, the DC offset holding module 416 may record the most recent estimate of the DC offset. This DC offset estimate (“current DC offset estimate”) may be used to minimize the DC offset associated with the receiver 400 from subsequently received baseband signals. In another implementation, after the DC offset estimation achieves a steady-state, the DC offset holding module 416 may record the steady-state value of the DC offset estimate. The DC offset estimation may achieve a steady-state when values of the DC offset estimated at consecutive iterations are equal or approximately equal. In some embodiments, the DC offset estimation module 414 may notify the DC offset holding module 416 when the steady-state is achieved. In another embodiment, the DC offset holding module 416 may keep track of the DC offset estimated by the DC offset estimation nodule 414 at each iteration. The DC offset holding module 416 may record the steady-state value of the DC offset as the current DC offset estimate.

The DC offset holding module 416 may provide the current DC offset estimate as an input to the subtractor 418. The ADC 406 may provide the digital representation of the baseband signal as another input to the subtractor 418. The baseband signal is a low pass signal that includes frequencies at or near DC frequency. In other words, the baseband signal includes a DC component. The DC component of the baseband signal may include the DC offset associated with the receiver 400 and a DC signal value. Thus, at least a portion of the DC component of the baseband signal includes the DC offset associated with the receiver 400. The subtractor 418 can subtract the current DC offset estimate from the DC component of the baseband signal to minimize the DC offset associated with the receiver 400. Specifically, the subtractor 418 can subtract the current DC offset estimate from each sample of the baseband signal generated by the ADC 406. The output of the subtractor 418 is a baseband signal with a minimized DC offset associated with the receiver 400. The output of the subtractor 418 may be provided for subsequent receiver processing. In one embodiment, the signal with the minimized DC offset (i.e., the output of the subtractor 418) may be provided to a radar detection module as described above with reference to FIG. 2.

In addition to controlling the gain setting of the receiver AFE 404, the AGC 408 may also provide a control signal to the DC offset estimation module 414 to indicate a change in the gain setting. The DC offset estimation module 414 may re-estimate the DC offset associated with the receiver 400 in response to receiving the control signal. In another embodiment, the DC offset estimation module 414 may re-estimate the DC offset associated with the receiver 400 in response to determining that a time interval has elapsed. In some embodiments, the time interval may be predetermined. In other embodiments, the time interval may be dynamically determined by the DC offset estimation module 414. The DC offset estimation module 414 may periodically re-estimate the DC offset associated with the receiver 400 to account for the drift in the DC offset because of variations in the ambient temperature, temperature of processing components of the receiver 400, humidity, and/or other environmental factors. In another embodiment, the DC offset estimation module 414 may continuously estimate the DC offset. In another embodiment, the DC offset estimation module 414 may re-estimate the DC offset in response to receiving a notification that the ADC 406 has saturated. The notification that the ADC 406 has saturated may be generated by the ADC 406, the AGC 408, or another suitable processing module of the receiver 400. In some embodiments, the DC offset estimation module 414 may initiate another quiet time interval for re-estimating the DC offset associated with the receiver 400. The DC offset estimation module 414 may estimate a new DC offset during the quiet time interval. In another embodiment, the DC offset estimation module 414 may not initiate another quiet time interval for re-estimating the DC offset. Instead, the DC offset estimation module 414 may estimate the new DC offset using baseband signals that are received at the receiver 400. In this embodiment, the DC offset holding module 412 may continue to provide the current DC offset estimate for cancelling the DC offset associated with the receiver 400 from the baseband signals while the DC offset estimation module 414 determines the new DC offset estimate.

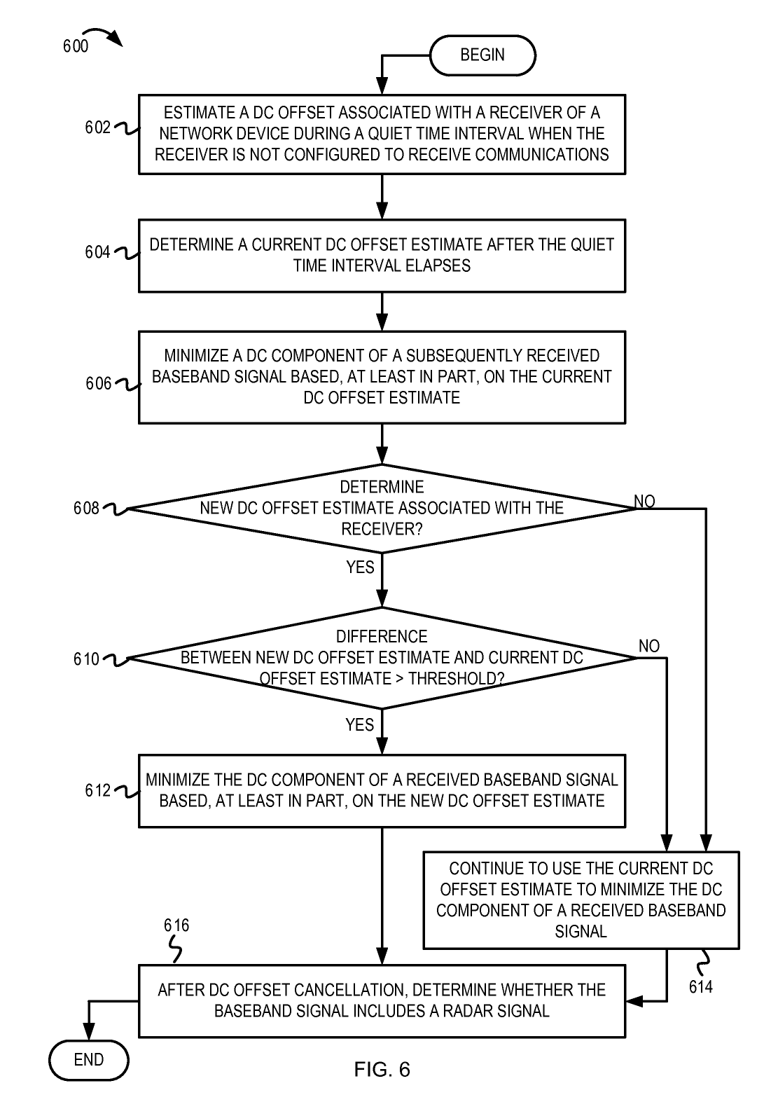

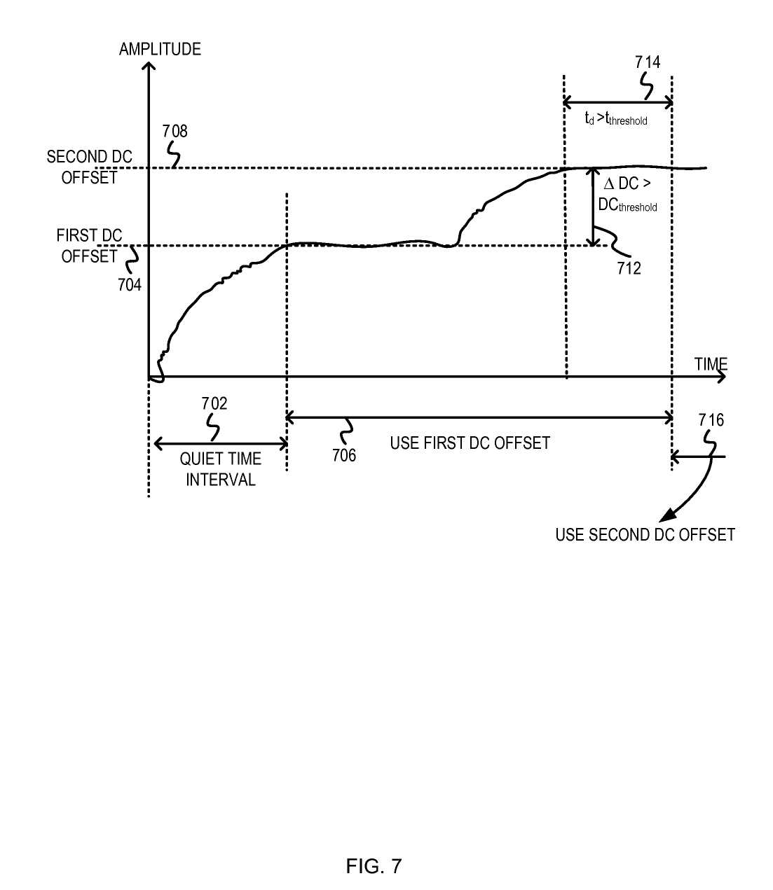

After estimating the new DC offset, the DC offset estimation module 414 (or the DC offset holding module 416) may compare the new DC offset estimate against the current DC offset estimate. In some embodiments, the DC offset holding module 416 may use the new DC offset estimate to minimize the DC offset associated with the receiver 400 from subsequently received baseband signals if the new DC offset estimate differs from the current DC offset estimate by at least a threshold value. In another embodiment, the DC offset holding module 416 may use the new DC offset estimate if the new DC offset estimate differs from the current DC offset estimate by at least a threshold value for at least a time interval. In some examples, the time interval may be a programmable, hardcoded, or dynamically determined time interval. In another embodiment, the DC offset holding module 416 may use the new DC offset estimate if the new DC offset estimate exceeds (or falls below) a certain quantization level for at least a predefined time interval. Operations of the DC offset cancellation module 412 will be further described in FIGS. 6 and 7.

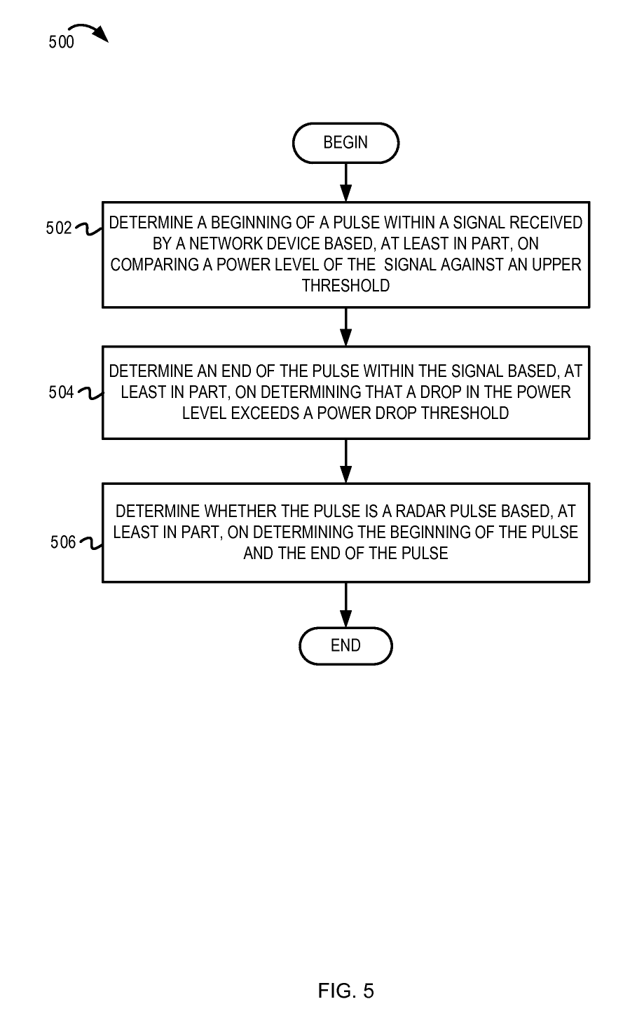

FIG. 5 is a flow diagram (“flow”) 500 illustrating example operations for detecting a radar pulse within a received signal. The flow 500 begins at block 502.

At block 502, a network device determines a beginning of a pulse within a signal received by the network device based, at least in part, on comparing a power level of the signal against an upper threshold. In one embodiment, an RF signal may be received by a wireless device configured to operate in the 5 GHz frequency band that overlaps with the operating frequency band for radar communications. Referring to the example of FIG. 1, the receiver processing module 104 may amplify, filter, and/or down-convert the RF signal. In some embodiments, the radar detection module 106 may analyze a baseband representation of the RF signal (i.e., a baseband signal) or the RF signal to determine whether the baseband signal (or the RF signal) includes a radar pulse. In other embodiments, the receiver processing unit 104 may down-convert the RF signal to an intermediate signal at an intermediate frequency. The radar detection module 106 may analyze the intermediate signal to determine whether the intermediate signal includes a radar pulse. The signal that is to be analyzed for radar detection (e.g., the RF signal, the baseband signal, or the intermediate signal) may be converted from an analog representation to a corresponding digital representation to yield a “digital received signal.”

The radar detection module 106 may compare the power level of the digital received signal against an upper threshold. In one embodiment, the time instant at which the power level exceeds the upper threshold may be recorded as the beginning of the pulse. In another embodiment, the radar detection module 106 may initiate a detection time interval in response to determining that the power level exceeds the upper threshold. The time instant at which the power level exceeds the upper threshold may be recorded as the beginning of the pulse in response to determining that the power level exceeds the upper threshold for at least the detection time interval. In other embodiments, the radar detection module 106 may use the amplitude level or the received signal strength information (RSSI) to determine the beginning of the pulse. In some embodiments, the DC offset cancellation module 108 may minimize the DC offset associated with the receiver 100 from the baseband signal prior to the radar detection module 106 determining the beginning of the pulse within the baseband signal. The flow continues at block 504.

At block 504, the network device determines an end of the pulse within the received signal based, at least in part, on determining that a drop in the power level exceeds a power drop threshold. After detecting the beginning of the pulse, the radar detection module 106 may continue to monitor the power level of the digital received signal to detect the end of the pulse. For example, the radar detection module 106 may detect a drop in the power level from a first power level to a second power level. The drop in the power level (“power drop”) may be determined as a difference between the first power level and the second power level. The radar detection module 106 may also determine the time instant (“first time instant”) at which the power drop was detected. In some embodiments, the power drop may be detected with reference to the power level of the RF signal at another time instant that precedes the first time instant. In another embodiment, the power drop may be detected with reference to the power level at the beginning of pulse. In other embodiments, the radar detection module 106 may use the amplitude level or the RSSI to determine a corresponding amplitude drop or RSSI drop. After determining the power drop, the radar detection module 106 may compare the power drop against a power drop threshold.

In some embodiments, if the power drop exceeds the power drop threshold, the first time instant at which the power drop was detected may be recorded as the end of the pulse or the falling edge of the pulse. In another embodiment, the first time instant may be recorded as the end of the pulse in response to determining that the power drop exceeds the power drop threshold for at least the detection time interval. Although not depicted in FIG. 5, if the power drop does not exceed the power drop threshold for at least the detection time interval, the radar detection module 106 can determine that drop in the power level was because of transient noise or interference in the communication network. In this scenario, the radar detection module 106 may continue to monitor the power level to detect a drop in the power level. After determining the end of the pulse, the flow continues at block 506.

At block 506, the network device determines whether the pulse is a radar pulse based, at least in part, on determining the beginning of the pulse and the end of the pulse. For example, the radar detection module 106 may determine pulse characteristics based, at least in part, on the beginning and the end of the pulse. The pulse characteristics may include the pulse width, the pulse repetition interval, the number of pulses detected in a time interval, and/or other pulse characteristics. The pulse characteristics may be compared against reference pulse characteristics of known radar signals to determine whether the pulse is part of a radar signal. If the pulse characteristics do not match the reference pulse characteristics, this can indicate that the detected pulse is not a radar pulse and that the received signal does not include a radar signal. If there is a match, this can indicate that the detected pulse is a radar pulse and that the received signal includes a radar signal. In some embodiments, the network device (e.g., a WLAN transceiver) can vacate at least a portion of the current operating frequency band in response to determining that the detected pulse is a radar pulse. In another embodiment, the network device can temporarily cease communications in the current operating frequency band until the radar signal is no longer detected in the operating frequency band. From block 506, the flow ends.

FIG. 6 is a flow diagram 600 illustrating example operations for DC offset cancellation prior to radar detection. The flow 600 begins at block 602.

At block 602, a network device estimates a DC offset associated with a receiver of the network device during a quiet time interval when the receiver is configured not to receive communications. In some embodiments, the quiet time interval may be initiated at the receiver by temporarily disabling the antenna of the receiver. In another embodiment, to initiate the quiet time interval, the receiver may broadcast a message to other network devices indicating that the receiver is not available to receive communications. In some embodiments, the receiver may demodulate RF signals directly into a baseband signal. However, a DC offset may be superposed onto the baseband signal after demodulation by the receiver. Referring to the example of FIG. 4, the DC offset estimation module 414 may analyze the output of the receiver processing module 410 during the quiet time interval. Because the receiver 400 is not receiving any RF signals, the output of the receiver processing module 410 can represent the DC offset associated with the receiver 400. The DC offset estimation module 414 may implement a suitable DC offset estimation technique. For example, the DC offset estimation module 414 may implement a leaky bucket technique for estimating the DC offset associated with the receiver 400. FIG. 7 is an example graph of signal amplitude (Y-axis) versus time (X-axis) illustrating DC offset estimation. The quiet time interval 702 is initiated at the network device. During the quiet time interval 702, the DC offset estimation may be iteratively executed until the quiet time interval 702 elapses. Referring back to FIG. 6, the flow continues at block 604.

At block 604, the network device determines a current DC offset estimate after the quiet time interval elapses. For example, the DC offset holding module 416 may record the value of the DC offset at the output of the DC offset estimation module 414 after the quiet time interval elapses. In some embodiments, after the DC offset estimation converges to a steady-state, the DC offset holding module 416 may record the steady-state value of the DC offset as the current DC offset estimate. The current DC offset estimate may then be used to minimize the DC offset from baseband signals that are subsequently received at the receiver 400. Referring to FIG. 7, the first DC offset estimate 704 is the DC offset estimate after the quiet time interval 702 elapses. The first DC offset estimate 704 is then used to cancel the DC offset associated with the receiver from subsequently received baseband signals. In FIG. 7, the first DC offset estimate 704 is used to cancel the DC offset from baseband signals received during time interval 706. Referring back to FIG. 6, the flow continues at block 606.

At block 606, the network device minimizes a DC component of a subsequently received baseband signal based, at least in part, on the current DC offset estimate. At least a portion of the DC component of the baseband signal is caused by a DC offset associated with the receiver. After the quiet time interval elapses, the receiver 400 may activate the antenna 402 and begin receiving RF signals from other network devices. In some embodiments, after the quiet time interval elapses, the receiver 400 may broadcast a message to other network devices indicating that the receiver 400 is available to receive communications. The receiver 400 may receive an RF signal via the antenna 402 and provide the RF signal to the receiver AFE 404. The receiver AFE 404 may amplify the signal, filter the signal, convert the RF signal into a baseband signal, etc. The ADC 406 may convert the analog representation of the baseband signal to a digital representation of the baseband signal. The digital representation of the baseband signal may be provided to the DC offset cancellation module 412 to minimize the DC offset associated with the receiver 400 from the baseband signal. As discussed above, the DC offset associated with the receiver 400 may include a combination of DC offset injected by one or more processing components of the receiver during their respective processing stage.

Referring to the example of FIG. 4, the subtractor 418 receives two inputs—the current DC offset estimate determined at block 604 and the digital representation of the baseband signal. The baseband signal may be a low pass signal that includes frequencies at or near DC frequency. Therefore, the DC component of the baseband signal may include the DC offset associated with the receiver 400 and a DC signal value. In other words, at least a portion of the DC component of the baseband signal may include the DC offset associated with the receiver 400. The subtractor 418 can subtract the current DC offset estimate from the DC component of the baseband signal to minimize the DC offset associated with the receiver 400. For example, the subtractor 418 can subtract the current DC offset estimate from each sample of the baseband signal to minimize the DC offset associated with the receiver 400. The flow continues at block 608.

At block 608, the network device determines whether to estimate a new DC offset associated with the receiver. In some embodiments, the new DC offset estimate may be determined after a programmable (or hardcoded) time interval elapses. The DC offset estimation module 414 may periodically re-estimate the DC offset associated with the receiver to account for the drift in the DC offset because of fluctuations in temperature, humidity, etc. For example, the DC offset estimation module 414 may initiate another quiet time interval to determine the new DC offset estimate. As another example, the DC offset estimation module 414 may use the received baseband signal to determine the new DC offset estimate without initiating another quiet time interval. In another embodiment, the new DC offset estimate may be determined in response to detecting a change in the gain setting associated with the receiver. For example, the new DC offset estimate may be determined in response to receiving a gain change notification from an AGC. As another example, the new DC offset estimate may be determined in response to receiving an ADC saturation notification. The DC offset estimation module 414 may initiate the quiet time interval to determine the new DC offset estimate or may use the received baseband signals to determine the new DC offset estimate without initiating the quiet time interval. In another embodiment, the DC offset estimation module 414 may continuously estimate the DC offset associated with the receiver and track the variation in the DC offset. If it is determined to estimate a new DC offset associated with the receiver, the flow continues at block 610. Otherwise, the flow continues at block 614.

At block 610, the network device determines whether the difference between the new DC offset estimate and the current DC offset estimate exceed a threshold. In some embodiments, the DC offset holding module 416 may compare the absolute value of the difference between the new DC offset estimate and the current DC offset estimate against a DC offset threshold. This can help determine whether to update the current DC offset estimate with the new DC offset estimate or whether to continue using the current DC offset estimate to minimize the DC component of the baseband signal received at the receiver. In some embodiments, the DC offset holding module 416 may determine whether the difference between the new DC offset estimate and the current DC offset estimate exceeds the DC offset threshold for at least a threshold time interval. This may help to determine that the change in the current DC offset estimate was not caused by a transient noise signal. As another example, the DC offset holding module 416 may determine whether the new DC offset estimate exceeds (or falls below) a certain quantization level for a predefined time interval. Referring to FIG. 7, the difference between the second DC offset estimate 708 (i.e., the new DC offset estimate) and the first DC offset estimate 704 (i.e., current DC offset estimate) is determined. The difference 712 between the second DC offset estimate 708 and the first DC offset estimate 704 (depicted as Δ DC) is compared against the DC offset threshold (DC_{threshold}). Referring back to FIG. 6, if the difference between the new DC offset estimate and the current DC offset estimate exceeds the threshold, the flow continues at block 612. Otherwise, the flow continues at block 614.

At block 612, the network device minimizes the DC component of the baseband signal based, at least in part, on the new DC offset estimate. Referring to FIG. 7, the difference 712 between the second DC offset estimate 708 and the first DC offset estimate 704 exceeds the DC offset threshold (e.g., Δ DC>DC_{threshold}). Additionally, the difference 712 exceeds the DC offset threshold for a threshold time interval 714 (t_{d}>t_{threshold}). Accordingly, the second DC offset 708 is used to minimize the DC offset associated with receiver from baseband signals that are received during a subsequent time interval 716. For example, the subtractor 418 can subtract the new DC offset estimate from the DC component of a received baseband signal to minimize the DC offset associated with the receiver. Referring back to FIG. 6, the flow continues at block 616.

At block 614, the network device continues to use the current DC offset estimate to minimize the DC component of a received baseband signal. For example, the subtractor 418 can subtract the current DC offset estimate from the DC component of a received baseband signal to minimize the DC offset associated with the receiver. The flow continues at block 616.

At block 616, after DC offset cancellation, the network device determines whether the baseband signal includes a radar signal. For example, the radar detection module 106 may determine whether a radar pulse was received as part of the baseband signal. The radar detection module 106 may determine the beginning of the pulse by detecting an increase in received signal power. The radar detection module 106 may determine the end of the pulse by detecting a decrease in the received signal power or a drop in the power level as described with reference to FIGS. 1-3A, 5, and 8-10. Pulse characteristics may be determined based, at least in part, on the beginning of the pulse and the end of the pulse. The pulse characteristics may then be used to determine whether the detected pulse is a radar pulse and consequently, whether the baseband signal includes a radar signal. From block 616, the flow ends.

Although not depicted in FIG. 6, after determining that the difference between the new DC offset estimate and the current DC offset estimate exceeds the threshold (i.e., “yes” path from block 610), the DC offset estimation module 414 may optionally initiate a detection time interval. Using the detection time interval may help minimize the possibility of false detection. If the difference exceeds the threshold for at least the detection time interval, this can indicate that the new DC offset estimate is substantially different from the current DC offset estimate and that the change in the current DC offset estimate is not attributable to transient noise and interference effects. If the difference exceeds the threshold for at least the detection time interval, the DC offset cancellation module 412 may use the new DC offset estimate to minimize the DC offset associated with the receiver from subsequently received baseband signals (e.g., block 612). Otherwise the DC offset cancellation module 412 may continue to use the current DC offset estimate to minimize the DC offset associated with the receiver from subsequently received baseband signals (e.g., block 614).

Although not depicted FIG. 6, after selecting either the current DC offset estimate or the new DC offset estimate, the network device may continue to determine whether to re-estimate the DC offset associated with the receiver. In this embodiment, the flow 600 may loop back from block 612 (or block 614) to block 608. Additionally, as depicted in FIG. 6, the flow may also move from block 612 (or block 614) to block 616).

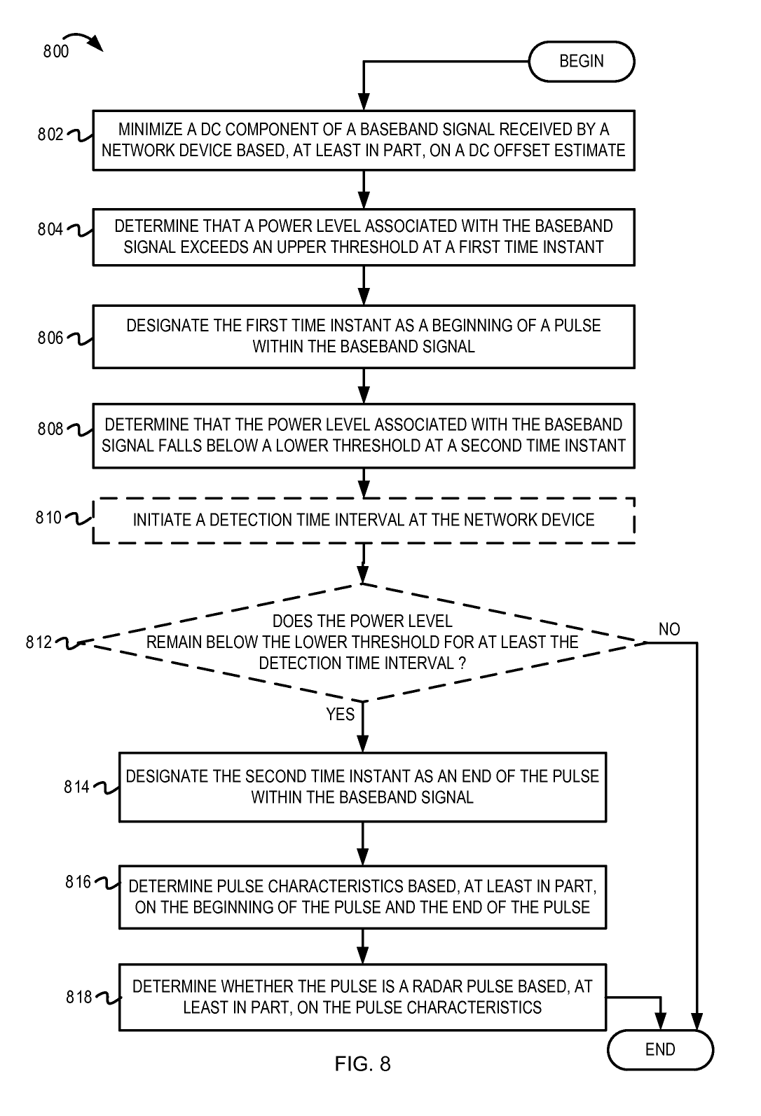

FIG. 8 is a flow diagram 800 illustrating operations of one embodiment of estimating pulse characteristics for radar detection. The flow 800 begins at block 802.

At block 802, a network device minimizes a DC component of a received baseband signal based, at least in part of a DC offset estimate. Referring to the example of FIG. 2, the antenna 202 may receive an RF signal. In one embodiment, the RF signal may be received by a wireless transceiver that is configured to operate in the 5 GHz frequency band that overlaps with the operating frequency band for radar communications. The receiver processing module 104 may amplify, filter, and/or down-convert the RF signal to generate a baseband representation of the RF signal (i.e., a baseband signal). In addition, the receiver processing module 104 (e.g., an AGC) may select an appropriate gain setting for receiving the RF signal. The receiver processing module 104 (e.g., an ADC) may also convert the baseband signal from an analog representation to a digital representation. The DC offset cancellation module 108 may estimate the DC offset associated with a receiver of the network device. The DC offset cancellation module 108 may subtract the DC offset estimate from a DC component of the baseband signal to minimize the DC offset associated with the receiver from the baseband signal. The resultant baseband signal after DC offset cancellation may be provided to the radar detection module 106 to determine whether the baseband signal includes a radar signal as will be further described below. The flow continues at block 804.

At block 804, the network device determines that a power level associated with the baseband signal exceeds an upper threshold at a first time instant. Referring to the example of FIG. 3A, in some embodiments, an FFT unit 302 may determine a frequency domain signal from the time domain representation of the baseband signal. If the frequency domain signal indicates the presence of a narrowband signal (i.e., a potential radar pulse) in an in-band communication channel of the network device, the pulse detector 304 can determine whether the baseband signal includes a radar signal. In other embodiments, the pulse detector 304 may not analyze the frequency domain representation of the baseband signal prior to executing operations for radar detection. The pulse detector 304 may compare the power level of the baseband signal against the upper threshold. Based on this comparison, the pulse detector 304 may determine that the power level exceeds the upper threshold at the first time instant. In other embodiments, the pulse detector 304 may use the amplitude level or the RSSI to determine the first time instant. The flow continues at block 806.

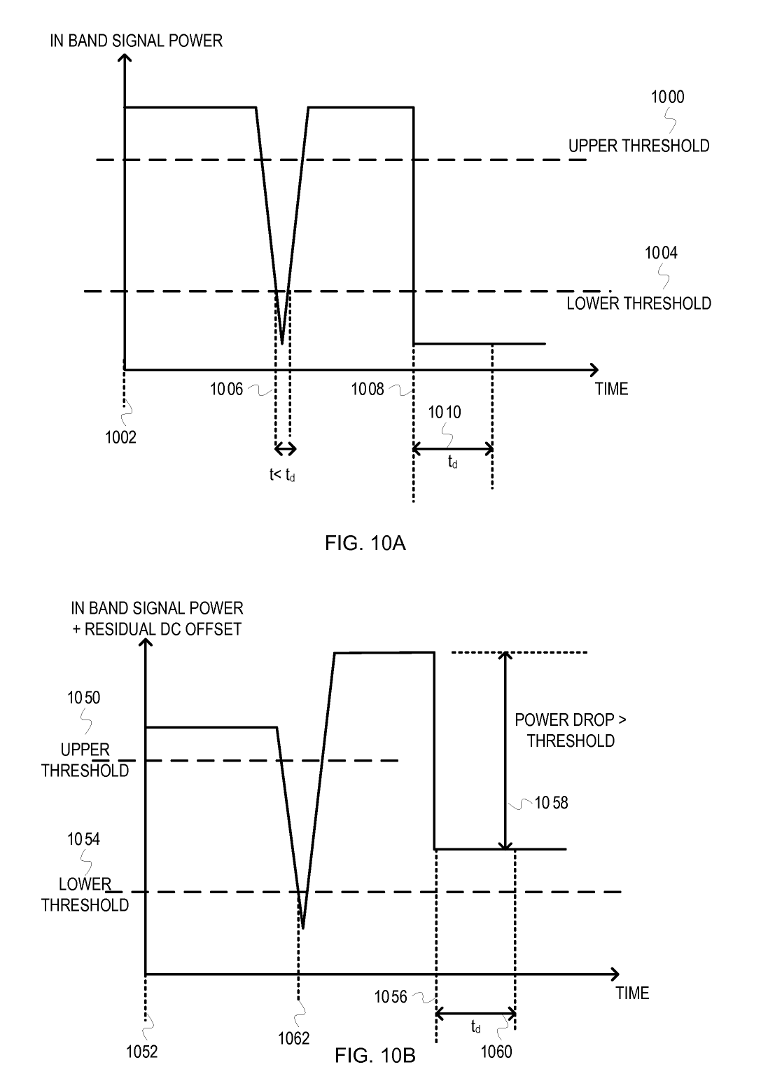

At block 806, the network device designates the first time instant as a beginning of a pulse within the baseband signal. For example, the pulse detector 304 may determine that the power level of the baseband signal exceeds the upper threshold at the first time instant. In some embodiments, the pulse detector 304 may record the first time instant as the beginning of the pulse or the rising edge of the pulse. FIG. 10A is a graph of in-band signal power (Y-axis) versus time (X-axis). The in-band signal power exceeds an upper threshold 1000 at time instant 1002. The time instant 1002 may be recorded as the beginning of the pulse. In some embodiments, the pulse detector 304 may initiate a detection time interval in response to determining that the power level of the baseband signal exceeds the upper threshold. The detection time interval may be initiated to minimize the possibility of false detection of the start of the pulse. Thus, maintaining the detection time interval can help filter out transient changes (e.g., noise spikes) which may incorrectly register as the rising edge of the pulse. If the power level exceeds the upper threshold for at least the detection time interval, the pulse detector 304 may record the first time instant as the beginning of the pulse. The flow continues at block 808.

At block 808, the network device determines that the power level associated with the baseband signal falls below a lower threshold at a second time instant. After detecting the beginning of the pulse, the pulse detector 304 may continue to monitor the power level of the baseband signal to detect the end of the pulse. For example, the pulse detector 304 may compare the power level of the baseband signal against the lower threshold to detect the end of the pulse. In other embodiments, the pulse detector 304 may use the amplitude level or the RSSI to determine the end of the pulse. The flow continues at block 810.

At block 810, the network device initiates a detection time interval. For example, the pulse detector 304 may initiate the detection time interval in response to determining that the power level of the signal drops below the lower threshold at the second time instant. Referring to the example of FIG. 10A, the pulse detector 304 initiates a detection time interval 1010 in response to determining that the in-band signal power drops below the lower threshold 1004. The detection time interval may be initiated to minimize the possibility of false detection of the end of the pulse. Thus, maintaining the detection time interval can help filter out transient changes (e.g., noise spikes) which may incorrectly register as a falling edge of the pulse. In FIG. 10A, the in-band signal power drops below the lower threshold 1004 at time instant 1006. However, the in-band signal power does not remain below the lower threshold 1004 for the detection time interval 1010. Accordingly, the decrease in in-band signal power at the time instant 1006 may be considered a transient power drop and may not be designated as the end of the pulse. In some embodiments, the detection time interval for determining the beginning of the pulse may be different from the detection time interval for determining the end of the pulse. In other embodiments, the detection time interval for determining the beginning of the pulse may be the same as the detection time interval for determining the end of the pulse. The flow continues at block 812.

At block 812, the network device determines whether the power level remains below the lower threshold for at least the detection time interval. If the power level remains below the lower threshold for at least the detection time interval, the flow moves to block 814. If the power level does not remain below the lower threshold for at least the detection time interval, the pulse detector 304 can determine that drop in the power level was because of transient noise or interference in the communication network. If the power level does not remain below the lower threshold for at least the detection time interval, the flow ends. Blocks 810 and 812 are depicted using dashed lines to indicate that the operations described in blocks 810 and 812 are optional.

At block 814, the network device designates the second time instant as an end of the pulse within the baseband signal. If the power level remains below the lower threshold for at least the detection time interval, the pulse detector 304 may record the second time instant as the end of the pulse or the falling edge of the pulse. In the example of FIG. 10A, the in-band signal power drops below the lower threshold 1004 at time instant 1008. The in-band signal power remains below the lower threshold 1004 for the detection time interval 1010. Accordingly, the time instant 1008 may be recorded as the end of the pulse. Referring back to FIG. 8, the flow continues at block 816.

At block 816, the network device determines pulse characteristics based, at least in part, on the beginning of the pulse and the end of the pulse. For example, the pulse analyzer 306 may determine the pulse width by subtracting the first time instant that corresponds to the beginning of the pulse from the second time instant that corresponds to the end of the pulse. In some embodiments, if multiple consecutive pulses are detected, the pulse analyzer 306 may determine the time interval between consecutive detected pulses. In some embodiments, the pulse analyzer 306 may also determine the number of pulses that were detected within a time interval. The pulse characteristics may include the pulse width, the pulse repetition interval, the number of pulses per time interval and/or other suitable characteristics The pulse characteristics may be used to determine whether the detected pulse is part of a radar signal and the type of the radar signal. The flow continues at block 818.

At block 818, the network device determines whether the pulse is a radar pulse based, at least in part, on the pulse characteristics. Known radar signals can have a predetermined pulse width, a predetermined pulse repetition interval, a predetermined number of pulses within a certain time period (i.e., burst period), and/or other predetermined characteristics, such as those defined by regulatory bodies (e.g., Federal Communications Commission (FCC), European Telecommunications Standards Institute (ETSI)). Although a known radar signal can have a relatively large number of pulses in a burst period, not all pulses need to be detected or received in the baseband signal to identify the radar signal. In one embodiment, detecting a subset of pulses in the baseband signal may be sufficient to determine whether the pulse is part of a known radar signal. The pulse analyzer 306 may compare the pulse characteristics with reference pulse characteristics of known radar signals to determine whether the detected pulse is part of a radar signal. If a match is not found, the pulse analyzer 306 may determine that the detected pulse is not part of a radar signal. Consequently, the pulse analyzer 306 may determine that the baseband signal does not include a radar signal. However, if a match is found, the pulse analyzer 306 may determine that the detected pulse is part of a radar signal. Consequently, the pulse analyzer 306 may determine that the baseband signal includes a radar signal. In some embodiments, the network device (e.g., a WLAN transceiver) can vacate at least a portion of the current operating frequency band in response to determining that the baseband signal includes a radar signal. In another embodiment, the network device can temporarily cease communications in the current operating frequency band until the radar signal is no longer detected in the operating frequency band. From block 818, the flow ends.

Although FIG. 8 describes the pulse detector 304 initiating the detection time interval at block 810, embodiments are not so limited. In other embodiments, the pulse detector 304 may not execute operations described in blocks 810 and 812. In other words, the pulse detector 304 may not initiate the detection time interval in response to determining that the power level drops below the lower threshold. Instead, in response to determining that the power level of the signal drops below the lower threshold at the second time instant, the pulse detector 304 may record the second time instant as the end of the pulse.

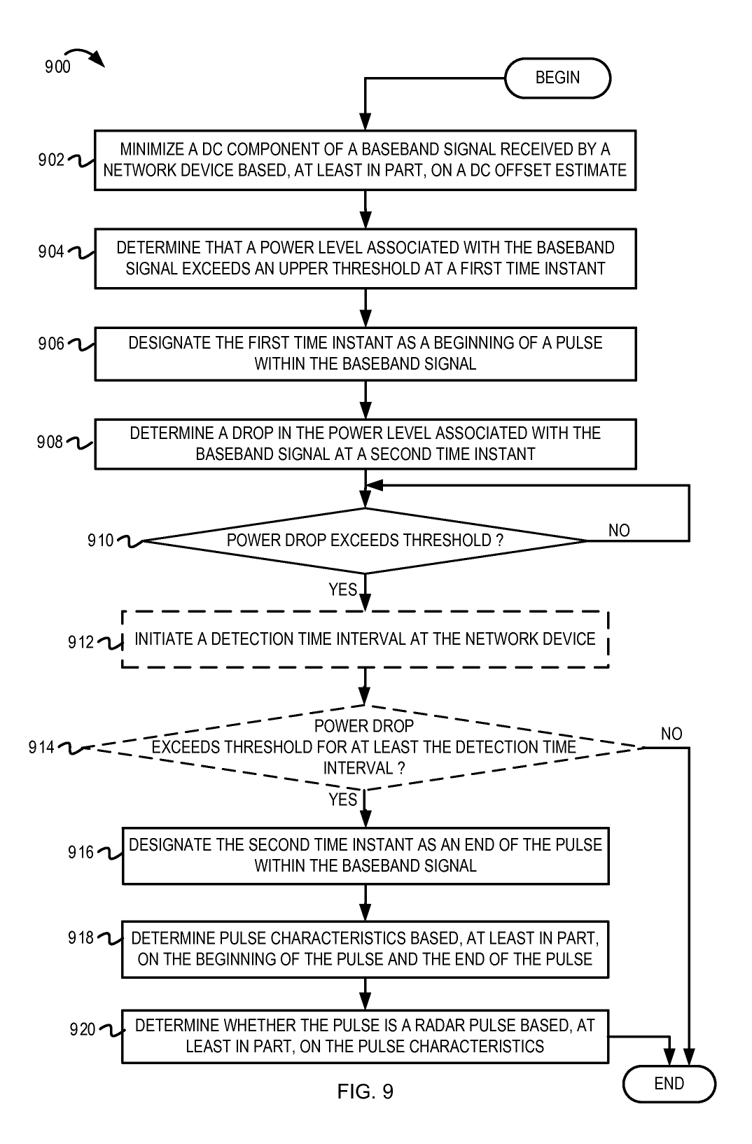

FIG. 9 is a flow diagram 900 illustrating operations of another embodiment of estimating pulse characteristics for radar detection. The flow 900 begins at block 902.

At block 902, a network device minimizes a DC component of a received baseband signal based, at least in part of a DC offset estimate. Referring to the example of FIG. 3A, the antenna 202 may receive an RF signal. In one embodiment, the RF signal may be received by a wireless transceiver configured to operate in the 5 GHz frequency band that overlaps with the operating frequency band for radar communications. The receiver processing module 104 may amplify, filter, and/or down-convert the RF signal to generate a baseband signal. In addition, the receiver processing module 104 may select an appropriate gain setting for receiving the RF signal. The receiver processing module 104 (e.g., an ADC) may convert the baseband signal from an analog representation to a digital representation. The DC offset cancellation module 108 may estimate the DC offset associated with a receiver of the network device. The DC offset cancellation module 108 may subtract the DC offset estimate from a DC component of the baseband signal to minimize the DC offset associated with the receiver from the baseband signal. The resultant baseband signal after DC offset cancellation may be provided to the radar detection module 106 to determine whether the baseband signal includes a radar signal as will be further described below. The flow continues at block 904.

At block 904, the network device determines that a power level associated with the baseband signal exceeds an upper threshold at a first time instant. Referring to the example of FIG. 3A, in some embodiments, an FFT unit 302 may determine a frequency domain signal from the time domain representation of the baseband signal. If the frequency domain signal indicates the presence of a narrowband signal (i.e., a potential radar pulse) in an in-band communication channel of the network device, the pulse detector 304 can determine whether the baseband signal includes a radar signal. In other embodiments, the pulse detector 304 may not analyze the frequency domain representation of the baseband signal prior to executing operations for radar detection. The pulse detector 304 may compare the power level of the baseband signal against the upper threshold. Based on this comparison, the pulse detector 304 may determine that the power level exceeds the upper threshold at the first time instant. In other embodiments, the pulse detector 304 may use the amplitude level or the RSSI to determine the first time instant. The flow continues at block 906.

At block 906, the network device designates the first time instant as a beginning of a pulse within the baseband signal. For example, the pulse detector 304 may determine that the power level of the baseband signal exceeds the upper threshold at the first time instant. In some embodiments, the pulse detector 304 may record the first time instant as the beginning of the pulse or the rising edge of the pulse. FIG. 10B is a graph of in-band signal power (Y-axis) versus time (X-axis). The in-band signal power exceeds an upper threshold 1050 at time instant 1052. The time instant 1052 may be recorded as the beginning of the pulse. In some embodiments, the pulse detector 304 may initiate a detection time interval in response to determining that the power level of the baseband signal exceeds the upper threshold. The detection time interval may be initiated to minimize the possibility of false detection of the start of the pulse. Thus, maintaining the detection time interval can help filter out transient changes (e.g., noise spikes) which may incorrectly register as the rising edge of the pulse. If the power level exceeds the upper threshold for at least the detection time interval, the pulse detector 304 may record the first time instant as the beginning of the pulse. The flow continues at block 908.

At block 908, the network device determines a drop in the power level associated with the baseband signal at a second time instant. Referring to the example of FIG. 10B, in some embodiments, the DC offset cancellation performed at block 902 may not completely eliminate the DC offset associated with the receiver. Therefore, the in-band signal power may have a residual DC offset. The presence of the residual DC offset may affect the ability to determine when the in-band signal power drops below a lower threshold 1054 (e.g., to detect the end of the pulse). In FIG. 10B, in the absence of the residual DC offset, the in-band signal power would have dropped below the lower threshold 1054 at time instant 1056. However, the superposition of the residual DC offset on the in-band signal power prevents the in-band signal power from dropping below the lower threshold 1054. To avoid the possibility of missing the end of the pulse, the drop in the power level can be determined.

After detecting the beginning of the pulse, the pulse detector 304 may continue to monitor the power level of the baseband signal to detect the end of the pulse. For example, the pulse detector 304 may detect a drop in the power level from a first power level to a second power level. The second power level may be the power level of the baseband signal at the second time instant. In some embodiments, the first power level may be the power level of the baseband signal at the beginning of the pulse. In other embodiments, the first power level may not correspond to the beginning of the pulse. Instead, the first power level may be the power level of the baseband signal at another time instant that precedes the second time instant. The power drop associated with the baseband signal may be determined as a difference between the first power level and the second power level. In the example of FIG. 10B, a power drop 1058 is determined at time instant 1056. In some embodiments, instead of the power level, the pulse detector 304 may monitor the amplitude level of the baseband signal and determine a drop in the amplitude level. Referring back to FIG. 9, the flow continues at block 910.

At block 910, the network device determines whether the power drop exceeds a power drop threshold. In the example of FIG. 10B, the power drop 1058 exceeds the power drop threshold. If the power drop exceeds the power drop threshold, the flow continues at block 912. Otherwise, the flow loops back to block 910.

At block 912, the network device initiates a detection time interval. For example, the pulse detector 304 may initiate the detection time interval in response to determining that the power drop exceeds the power drop threshold at the second time instant. Referring to the example of FIG. 10B, the pulse detector 304 initiates a detection time interval (t_{d}) 1060 in response to determining that the power drop 1058 exceeds the power drop threshold. The detection time interval may be initiated to minimize the possibility of false detection of the end of the pulse. Thus, maintaining the detection time interval can help filter out transient changes (e.g., noise spikes) which may incorrectly register as a falling edge of the pulse. In FIG. 10B, the network device may detect a power drop at time instant 1062. This power drop may exceed the power drop threshold. However, as depicted in FIG. 10B, the power drop at the time instant 1062 does not exceed the power drop threshold for the detection time interval 1060. Accordingly, the power drop at the time instant 1062 may be considered a transient power drop and may not be designated as the end of the pulse. In some embodiments, the detection time interval for determining the beginning of the pulse may be different from the detection time interval for determining the end of the pulse. In other embodiments, the detection time interval for determining the beginning of the pulse may be the same as the detection time interval for determining the end of the pulse. The flow continues at block 914.

At block 914, the network device determines whether the power drop exceeds the power drop threshold for at least the detection time interval. If the power drop exceeds the power drop threshold for at least the detection time interval, the flow continues at block 916. If the power drop does not exceed the power drop threshold for at least the detection time interval, the pulse detector 304 can determine that drop in the power level was because of transient noise or interference in the communication network. If the power drop does not exceed the power drop threshold for at least the detection time interval, the flow ends. Blocks 912 and 914 are depicted using dashed lines to indicate that the operations described in blocks 912 and 914 are optional.

At block 916, the network device designates the second time instant as an end of the pulse within the baseband signal. If the power drop exceeds the power drop threshold for at least the detection time interval, the pulse detector 304 may record the second time instant as the end of the pulse or the falling edge of the pulse. In the example of FIG. 10B, the power drop 1058 determined at time instant 1056 exceeds the power drop threshold for the detection time interval 1060. Therefore, the time instant 1056 may be recorded as the end of the pulse. Referring back to FIG. 9, the flow continues at block 918.

At block 918, the network device determines pulse characteristics based, at least in part, on the beginning of the pulse and the end of the pulse. For example, the pulse analyzer 306 may determine pulse characteristics such as, the pulse width, the pulse repetition interval, the number of pulses detected within in a predetermined time interval, etc. The pulse characteristics may be compared against reference pulse characteristics of known radar signals to determine whether the detected pulse is part of a radar signal. The flow continues at block 920.

At block 920, the network device determines whether the pulse is a radar pulse based, at least in part, on the pulse characteristics. For example, the pulse analyzer 306 may compare the pulse characteristics with corresponding reference pulse characteristics of known radar signals as described above in FIG. 8. If pulse characteristics do not match the reference pulse characteristics, this can indicate that the detected pulse is not a radar pulse and that the baseband signal does not include a radar signal. If there is a match, this can indicate that the detected pulse is a radar pulse and that the baseband signal includes a radar signal. In some embodiments, the network device (e.g., a WLAN transceiver) can vacate at least a portion of the current operating frequency band in response to determining that the baseband signal includes a radar signal. In another embodiment, the network device can temporarily cease communications in the current operating frequency band until the radar signal is no longer detected in the operating frequency band. From block 920, the flow ends.

Although FIG. 9 describes the pulse detector 304 initiating the detection time interval at block 912, embodiments are not so limited. In other embodiments, the pulse detector 304 may not execute operations described in blocks 912 and 914. In other words, the pulse detector 304 may not initiate the detection time interval in response to determining that the power drop exceeds the power drop threshold. Instead, in response to determining that the power drop exceeds the power drop threshold at the second time instant, the pulse detector 304 may record the second time instant as the end of the pulse or the falling edge of the pulse.

It should be understood that FIGS. 1-10B and the operations described herein are examples meant to aid in understanding embodiments and should not be used to limit embodiments or limit scope of the claims. Embodiments may perform additional operations, fewer operations, operations in a different order, operations in parallel, and some operations differently. Although the Figures describe determining whether a baseband signal includes a radar pulse, embodiments are not so limited. In other embodiments, the techniques described herein may be implemented to determine whether an RF signal includes a radar pulse. In another embodiment, the techniques described herein may be implemented to determine whether another suitable signal (e.g., an intermediate (IF) signal) includes a radar pulse. Furthermore, in some embodiments, operations for DC offset cancellation may not be executed prior to determining whether the RF signal or the baseband signal includes a radar pulse.

Although examples refer to determining the beginning of the pulse and the end of the pulse using a digital representation of a received signal, in other embodiments, the beginning of the pulse and the end of the pulse may be determined using an analog representation of the received signal. In other embodiments, the beginning of the pulse may be determined using the analog representation of the received signal; while the end of the pulse may be determined using the digital representation of the received signal.

In some embodiments, the operations for DC offset cancellation may be executed only when a narrowband signal that potentially represents a radar pulse is detected at or near the DC frequency. For example, the DC offset cancellation module 412 may be enabled if the frequency domain representation of the baseband signal includes a peak at or near the DC frequency. A peak at or near the DC frequency can indicate the presence of a radar pulse in the baseband signal at or near the DC frequency. In this scenario, the DC component of the baseband signal may include a superposition of the DC offset associated with the receiver and the amplitude of the radar pulse. The DC offset cancellation module 412 may estimate the DC offset associated with of the receiver 400 and subtract the DC offset estimate from the DC component of the baseband signal. As another example, the DC offset cancellation module 412 may be disabled if the frequency domain representation of the baseband signal does not include a peak at or near the DC frequency. In other embodiments, the operations for DC offset cancellation may be performed irrespective of whether the frequency domain representation of the baseband signal includes a peak at or near the DC frequency.

In some embodiments, maintaining the detection time interval to detect the falling edge of the pulse can also help when the received baseband signal includes a chirping pulse. The chirping pulse is a pulse whose frequency changes over time. For example, the frequency of the chirping pulse may vary between a lower frequency f1 and an upper frequency f2, such that the DC frequency (i.e., 0 Hz) lies between the lower frequency and the upper frequency. In some embodiments, the chirping pulse may be part of a radar signal. In other embodiments, the chirping pulse may be part of a sound navigation and ranging (SONAR) signal or a spread-spectrum signal. In some embodiments, the end of the pulse may be determined as the time instant at which the power level of the baseband signal drops below a lower threshold for at least a detection time interval. In one example of this embodiment, the lower threshold may be equal to or approximately equal to the noise floor of the communication network. In some embodiments, the detection time interval may be determined based on the slowest chirp rate (i.e., the lower frequency of the chirping pulse) and/or the bandwidth of the DC offset estimation module (e.g., a leaky bucket filter). The slowest chirp rate may be used to estimate the detection time interval because the chirping pulse remains at or near the DC frequency for a longer time period when the chirping pulse has the slowest chirp rate.

In some embodiments, the DC offset estimation module may select an initial value of zero for estimating the DC offset associated with the receiver. In other embodiments, the DC offset estimation module may use a preceding DC offset estimate as the initial value for determining the current DC offset estimate associated with the receiver. The preceding DC offset estimate may be the last known value of the DC offset associated with the receiver. For example, the preceding DC offset estimate may be the DC offset estimate that was last used before the receiver was shut down or restarted. The DC offset estimation module may keep track of the preceding DC offset estimate for each gain setting of the receiver. After the AGC selects a gain setting, the DC offset estimation module may determine the preceding DC offset estimate that corresponds to the gain setting. The DC offset estimation module may use the preceding DC offset estimate to determine the current DC offset estimate for subsequent DC offset cancellation. Using the preceding DC offset estimate instead of a zero value as the initial value can improve the speed of convergence associated with determining the current DC offset estimate.

Although embodiments describe the DC offset estimation module 414 initiating a quiet time interval for initially estimating the DC offset associated with the receiver, embodiments are not so limited. In other embodiments, the DC offset estimation module 414 may not initiate the quiet time interval and may not estimate the DC offset during the quiet time interval. Instead, after start-up, the DC offset estimation module 414 may begin to estimate the current DC offset from a baseband signal based, at least in part, on a preceding DC offset estimate. In parallel, the DC offset holding module 416 may provide the preceding DC offset estimate to the subtractor 418 to cancel the DC offset associated with the receiver from the baseband signal. Once the DC offset estimation module 414 estimates the current DC offset, the DC offset holding module 416 can discard the preceding DC offset estimate and use the current DC offset estimate for cancelling the DC offset associated with the receiver 400 from subsequent baseband signals.

In some embodiments, bandwidth of the DC offset estimation module 414 may be configurable to adjust the convergence speed of the DC offset estimation module 414. For example, the bandwidth of the DC offset estimation module 414 may be initially increased to include a larger frequency band centered around the DC frequency. The high bandwidth of the DC offset estimation module 414 may increase the convergence speed so that the DC offset estimation module 414 can determine a current DC offset estimate with a short quiet time interval. While the current DC offset estimate is being used to cancel the DC offset from baseband signals, the bandwidth of the DC offset estimation module 414 may be reduced to include a smaller frequency band centered around the DC frequency. The smaller bandwidth of the DC offset estimation module 414 may lower the convergence speed of the DC offset estimation module 414. This can enable the DC offset estimation module 414 to track the variations in the current DC offset estimate and to update the current DC offset estimate (if needed).

As will be appreciated by one skilled in the art, aspects of the present disclosure may be embodied as a system, method, or computer program product. Accordingly, aspects of the present disclosure may take the form of an entirely hardware embodiment, a software embodiment (including firmware, resident software, micro-code, etc.) or an embodiment combining software and hardware aspects that may all generally be referred to herein as a “circuit,” “module,” “unit,” or “system.” Furthermore, aspects of the present disclosure may take the form of a computer program product embodied in one or more computer readable medium(s) having computer readable program code embodied thereon.

Any combination of non-transitory computer readable medium(s) may be utilized. Non-transitory computer-readable media comprise all computer-readable media, with the sole exception being a transitory, propagating signal. The non-transitory computer readable medium may be a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Computer program code embodied on a computer readable medium for carrying out operations for aspects of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

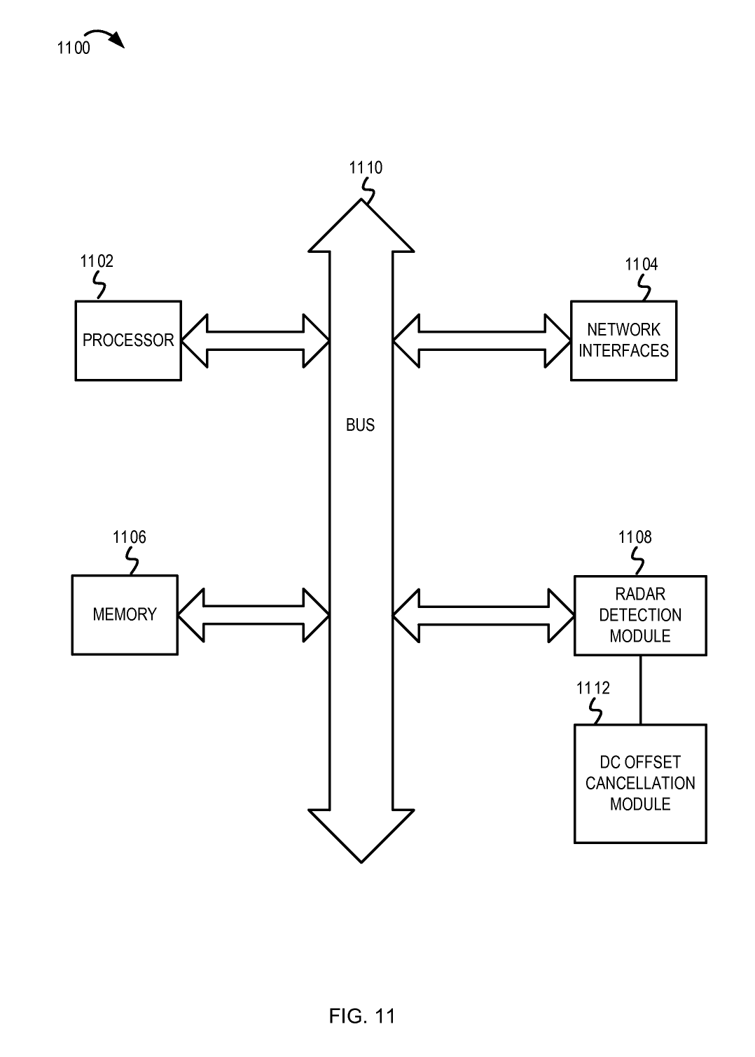

FIG. 11 is a block diagram of one embodiment of an electronic device 1100 including a mechanism for radar detection. In some embodiments, the electronic device 1100 can be a laptop computer, a tablet computer, a netbook, a mobile phone, a smart appliance, a gaming console, a desktop computer, a network bridge device, or another suitable electronic device that includes communication capabilities. For example, the electronic device 1100 may be any suitable communication device that is configured to operate in a frequency band that overlaps with a radar frequency band. As another example, the electronic device 1100 may be any suitable communication device that implements WLAN communication protocols (e.g., IEEE 802.11 communication protocols). The electronic device 1100 includes a processor 1102 (possibly including multiple processors, multiple cores, multiple nodes, and/or implementing multi-threading, etc.). The electronic device 1100 includes memory 1106. The memory 1106 may be system memory (e.g., one or more of cache, SRAM, DRAM, zero capacitor RAM, Twin Transistor RAM, eDRAM, EDO RAM, DDR RAM, EEPROM, NRAM, RRAM, SONOS, PRAM, etc.) or any one or more of the above already described possible realizations of computer-readable storage media. The electronic device 1100 also includes a bus 1110 (e.g., PCI, ISA, PCI-Express, HyperTransport®, InfiniBand®, NuBus, AHB, AXI, etc.) and network interfaces 1104. The processor 1102, the memory 1106, and the network interfaces 1104 are coupled to the bus 1110. The network interfaces 1104 include a wireless network interface (e.g., a WLAN interface, a Bluetooth® interface, a WiMAX interface, a ZigBee® interface, a Wireless USB interface, an LTE interface, a CDMA2000 interface, etc.) and/or a wired network interface (e.g., a PLC interface, an Ethernet interface, etc.). Furthermore, in some embodiments, the electronic device 1100 can execute IEEE 1905.1 protocols for implementing hybrid communication functionality.

The electronic device 1100 also includes a radar detection module 1108 and a DC offset cancellation module 1112. The radar detection module 1108 may determine whether a received RF signal or a baseband representation of the RF signal includes a radar pulse as described above in FIGS. 1-3B, 5, and 8-10B. In some implementations, the DC offset cancellation module 1112 may estimate a DC offset associated with a receiver of the electronic device 1100. The DC offset cancellation module 1112 may minimize the DC offset associated with the receiver from the baseband signal as described above in FIGS. 1, 4, and 6-7. After DC offset cancellation, the radar detection module 1108 may determine whether the resultant baseband signal includes a radar pulse.

Any one of these functionalities may be partially (or entirely) implemented in hardware and/or on the processor 1102. For example, the functionality of the radar detection module 1108 and/or the DC offset cancellation module 1112 may be implemented with an application specific integrated circuit (ASIC), in logic implemented in the processor 1102, in a co-processor on a peripheral device or card, etc. In some embodiments, the radar detection module 1108 and/or the DC offset cancellation module 1112 can be implemented on a system-on-a-chip (SoC), an ASIC, or another suitable integrated circuit to enable communication by the electronic device 1100. In some embodiments, the radar detection module 1108 and/or the DC offset cancellation module 1112 may include additional processors and memory, and may be implemented in one or more integrated circuits on one or more circuit boards of the electronic device 1100. Further, realizations may include fewer or additional components not illustrated in FIG. 11 (e.g., video cards, audio cards, additional network interfaces, peripheral devices, etc.). For example, in addition to the processor 1102 coupled with the bus 1110, the radar detection module 1108 and/or the DC offset cancellation module 1112 may include at least one additional processor. As another example, although illustrated as being coupled to the bus 1110, the memory 1106 may be coupled to the processor 1102.

While the embodiments are described with reference to various implementations and exploitations, it will be understood that these embodiments are illustrative and that the scope of the disclosure is not limited to them. In general, techniques for radar detection as described herein may be implemented with facilities consistent with any hardware system or hardware systems. Many variations, modifications, additions, and improvements are possible.

Plural instances may be provided for components, operations, or structures described herein as a single instance. Finally, boundaries between various components, operations, and data stores are somewhat arbitrary, and particular operations are illustrated in the context of specific illustrative configurations. Other allocations of functionality are envisioned and may fall within the scope of the disclosure. In general, structures and functionality presented as separate components in the exemplary configurations may be implemented as a combined structure or component. Similarly, structures and functionality presented as a single component may be implemented as separate components. These and other variations, modifications, additions, and improvements may fall within the scope of the disclosure.

What is claimed is:

1. A method comprising:
determining a beginning of a pulse within a first signal received by a network device based, at least in part, on comparing a power level of the first signal against an upper threshold;
determining an end of the pulse within the first signal based, at least in part, on determining that a drop in the power level associated with the first signal exceeds a power drop threshold; and
determining whether the pulse is a radar pulse based, at least in part, on determining the beginning of the pulse and the end of the pulse.

2. The method of claim 1, further comprising:
determining a time instant when the drop in the power level exceeds the power drop threshold;
initiating a detection time interval at the network device in response to determining that the drop in the power level exceeds the power drop threshold; and
determining whether to designate the time instant as the end of the pulse after the detection time interval elapses.

3. The method of claim 1, wherein said determining the end of the pulse is in response to determining that the drop in the power level exceeds the power drop threshold for at least a detection time interval.

4. The method of claim 1, wherein said determining the beginning of the pulse comprises:
determining a time instant when the power level exceeds the upper threshold;
initiating a detection time interval at the network device in response to determining that the power level exceeds the upper threshold; and
designating the time instant as the beginning of the pulse in response to determining that the power level exceeds the upper threshold for at least the detection time interval.

5. The method of claim 1, wherein said determining whether the pulse is a radar pulse comprises:
determining a characteristic of the pulse based, at least in part, on the beginning of the pulse and the end of the pulse; and
comparing the characteristic of the pulse against a reference characteristic associated with a reference radar signal to determine whether the pulse is a radar pulse.

6. The method of claim 5, wherein the characteristic of the pulse includes at least one of a pulse width, a pulse repetition interval, and a number of pulses detected within a predetermined interval.

7. The method of claim 1, wherein said determining whether the pulse is a radar pulse comprises:
determining a characteristic of the pulse based, at least in part, on the beginning of the pulse and the end of the pulse;
determining that the characteristic of the pulse matches a reference characteristic associated with a reference radar signal; and
determining that the pulse is a radar pulse that corresponds to the reference radar signal.

8. The method of claim 1, further comprising:
converting a time domain representation of the first signal to a frequency domain representation of the first signal;
determining whether the frequency domain representation of the first signal includes a narrowband signal at a communication frequency on which the network device is configured to operate; and
monitoring the power level of the first signal to determine the beginning of the pulse in response to determining that the frequency domain representation of the first signal includes the narrowband signal.

9. The method of claim 1, further comprising:
determining a first DC offset estimate associated with a receiver of the network device;
adjusting a DC component of the first signal based, at least in part, on the first DC offset estimate, wherein at least a portion of the DC component of the first signal is generated by the receiver; and
monitoring the power level of the first signal to determine the beginning of the pulse after adjusting the DC component of the first signal.

10. The method of claim 9, further comprising:
determining a second DC offset estimate associated with the receiver in response to determining a change in a gain setting associated with the receiver.

11. The method of claim 9, further comprising:
determining whether a difference between a second DC offset estimate and the first DC offset estimate exceeds a DC offset threshold for a time interval, wherein the second DC offset estimate is determined subsequent to the first DC offset estimate;
adjusting, using the second DC offset estimate, a DC component of a second signal that is received after the first signal in response to determining that the difference exceeds the DC offset threshold; and
continuing to use the first DC offset estimate to adjust the DC component of the second signal in response to determining that the difference does not exceed the DC offset threshold.

12. A network device comprising:
a processor; and
a memory to store instructions, which when executed by the processor, cause the network device to:
determine a beginning of a pulse within a signal received by the network device based, at least in part, on comparing a power level of the signal against an upper threshold;
determine an end of the pulse within the signal based, at least in part, on determining that a drop in the power level associated with the signal exceeds a power drop threshold; and
determine whether the pulse is a radar pulse based, at least in part, on determining the beginning of the pulse and the end of the pulse.

13. The network device of claim 12, wherein causing the network device to determine the end of the pulse is in response to determining that the drop in the power level exceeds the power drop threshold for at least a detection time interval.

14. The network device of claim 12, wherein causing the network device to determine whether the pulse is a radar pulse comprises causing the network device to:
determine a characteristic of the pulse based, at least in part, on the beginning of the pulse and the end of the pulse;
determine that the characteristic of the pulse matches a reference characteristic associated with a reference radar signal; and
determine that the pulse is a radar pulse that corresponds to the reference radar signal.

15. The network device of claim 12, wherein the instructions, which when executed by the processor, cause the network device to:
convert a time domain representation of the signal to a frequency domain representation of the signal;
determine whether the frequency domain representation of the signal includes a narrowband signal at a communication frequency on which the network device is configured to operate; and
monitor the power level of the signal to determine the beginning of the pulse in response to determining that the frequency domain representation of the signal includes the narrowband signal.

16. The network device of claim 12, wherein the instructions, which when executed by the processor, cause the network device to:
determine a first DC offset estimate associated with a receiver of the network device;
adjust a DC component of the signal based, at least in part, on the first DC offset estimate, wherein at least a portion of the DC component of the signal is generated by the receiver; and
monitor the power level of the signal to determine the beginning of the pulse after adjusting the DC component of the signal.

17. A non-transitory machine-readable storage medium having machine executable instructions stored therein, the machine executable instructions comprising instructions to:
determine a beginning of a pulse within a signal received by a network device based, at least in part, on comparing a power level of the signal against an upper threshold;
determine an end of the pulse within the signal based, at least in part, on determining that a drop in the power level associated with the signal exceeds a power drop threshold; and
determine whether the pulse is a radar pulse based, at least in part, on determining the beginning of the pulse and the end of the pulse.

18. The non-transitory machine-readable storage medium of claim 17, wherein said instructions to determine the end of the pulse are in response to determining that the drop in the power level exceeds the power drop threshold for at least a detection time interval.

19. The non-transitory machine-readable storage medium of claim 17, wherein said instructions to determine whether the pulse is a radar pulse comprise instructions to:
determine a characteristic of the pulse based, at least in part, on the beginning of the pulse and the end of the pulse;
determine that the characteristic of the pulse matches a reference characteristic associated with a reference radar signal; and
determine that the pulse is a radar pulse that corresponds to the reference radar signal.

20. The non-transitory machine-readable storage medium of claim 17, wherein said instructions further comprise instructions to:
convert a time domain representation of the signal to a frequency domain representation of the signal;
determine whether the frequency domain representation of the signal includes a narrowband signal at a communication frequency on which the network device is configured to operate; and
monitor the power level of the signal to determine the beginning of the pulse after adjusting a DC component of the signal in response to determining that the frequency domain representation of the signal includes the narrowband signal, wherein at least a portion of the DC component of the signal is generated by a receiver of the network device.
